(19) United States
(12) Patent Application Publication
(10) Pub. No.: US 2023/0140263 A1
(43) Pub. Date: May 4, 2023

(54) SHOWERHEADS WITH HIGH SOLIDITY PLENUMS

(71) Applicant: LAM RESEARCH CORPORATION, Fremont, CA (US)

(72) Inventors: Manjunatha H. LAKSHMANA, Bangalore (IN); Sean M. Donnelly, Portland, OR (US); Srinivas Rao Hemanth Rao Kallurkar, Bangalore (IN); Arun Keshavamurthy, Bangalore (IN)

(21) Appl. No.: 17/877,046

(22) Filed: Jul. 29, 2022

Related U.S. Application Data
(60) Provisional application No. 63/227,616, filed on Jul. 30, 2021.

(51) Int. Cl. B05B 1/18; B05B 1/00; C23C 16/455

(52) U.S. Cl. CPC B05B 1/18; B05B 1/005; C23C 16/45565; H01J 37/3244

(57) ABSTRACT

Multiple single plenum and dual plenum showerhead designs are disclosed. In the designs, pillars are disposed in each plenum to increase solidity of the plenums to provide improved axial heat conduction through the showerheads. The heat conduction is further improved by providing solid and substantially conical backplates.

### FIELD

The present disclosure relates generally to substrate processing systems and more particularly to showerheads with high solidity plenums.

### BACKGROUND

The background description provided here is for the purpose of generally presenting the context of the disclosure. Work of the presently named Applicants, to the extent it is described in this background section, as well as aspects of the description that may not otherwise qualify as prior art at the time of filing, are neither expressly nor impliedly admitted as prior art against the present disclosure.

A substrate processing system typically comprises a plurality of stations (also called processing chambers or process modules) in which to perform deposition, etching, and other treatments on substrates such as semiconductor wafers. Examples of processes that may be performed on a substrate include a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate include, but are not limited to, etching (e.g., chemical etching, plasma etching, reactive ion etching, atomic layer etching (ALE), plasma enhanced ALE (PEALE), etc.) and cleaning processes.

During processing, a substrate is arranged on a substrate support such as a pedestal in a station. During deposition, gas mixtures including one or more precursors are introduced into the station, and plasma may be optionally struck to activate chemical reactions. During etching, gas mixtures including etch gases are introduced into the station, and plasma may be optionally struck to activate chemical reactions. A computer-controlled robot typically transfers substrates from one station to another in a sequence in which the substrates are to be processed.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. Thermal ALD (T-ALD) is carried out in a heated processing chamber. The processing chamber can be maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process. Atomic layer etching comprises a sequence alternating between self-limiting chemical modification steps that affect only top atomic layers of a substrate and etching steps that remove only the chemically-modified areas from the substrate. The sequence allows removal of individual atomic layers from the substrate.

### SUMMARY

A showerhead comprises a base portion and a backplate. The backplate has a different shape than the base portion and extends from the base portion. The showerhead comprises a plurality of pillars is arranged in a plenum defined between an upper region of the base portion and a lower region of the backplate within sidewalls of the base portion and the lower region of the backplate. The pillars extend vertically between the base portion and the lower region of the backplate.

In additional features, the base portion is cylindrical. The backplate comprises a cylindrical base and a conical portion. The cylindrical base is attached to the base portion. The conical portion extends from the cylindrical base.

In additional features, the backplate comprises a recess in a bottom region abutting the base portion. The base portion comprises the pillars that extend through the recess and contact the cylindrical base.

In additional features, the base portion comprises a recess in the upper region abutting the cylindrical base. The cylindrical base comprises the pillars that extend through the recess and contact the base portion.

In additional features, the showerhead further comprises a stem portion attached to the conical portion of the backplate. The stem portion comprises a gas inlet. The conical portion comprises a plurality of bores in fluid communication with the gas inlet. The bores extend towards the base portion and connecting to the plenum.

In additional features, the showerhead further comprises a stem portion attached to the conical portion of the backplate. The backplate comprises a plurality of bores extending from the stem portion towards the base portion for receiving a plurality of heaters, respectively.

In additional features, the showerhead further comprises a stem portion attached to the conical portion of the backplate. The backplate comprises one or more bores extending from the stem portion towards the base portion for receiving one or more temperature sensors, respectively.

In additional features, the showerhead further comprises a stem portion attached to the conical portion of the backplate. The stem portion comprises a gas inlet. The backplate comprises a first plurality of bores in fluid communication with the gas inlet. The first plurality of bores extends towards the base portion and connecting to the plenum. The backplate comprises a second plurality of bores extending from the stem portion towards the base portion for receiving a plurality of heaters, respectively. The backplate comprises one or more bores extending from the stem portion towards the base portion for receiving one or more temperature sensors, respectively. The first and second plurality of bores and the one or more bores are interstitial to each additional. The base portion comprises a plurality of through holes extending vertically from a bottom surface of the base portion to the plenum. The through holes are arranged interstitially with the pillars.

In additional features, the pillars are arranged in a first pattern. Each of the pillars is surrounded by a set of the through holes arranged in a second pattern.

In additional features, the first and second patterns are hexagonal.

In additional features, the base portion comprises a plurality of through holes extending vertically from a bottom surface of the base portion to the plenum. The through holes are arranged interstitially with the pillars.

In additional features, diameters of the base portion and the cylindrical base are equal.

In still other features, a showerhead comprises a base portion and a backplate. The backplate has a different shape than the base portion and extends from the base portion. The backplate and the base portion are monolithic. The showerhead comprises a plurality of pillars is arranged in a plenum defined within sidewalls of the base portion. The pillars extend vertically towards the backplate.

In additional features, the base portion is cylindrical. The backplate comprises a conical portion extending from the base portion. The conical portion and the base portion are monolithic.

In additional features, the base portion comprises a plurality of sets of bores extending across the base portion. The sets of bores intersect each additional. Intersections of the sets of bores define the pillars.

In additional features, the sets of bores have first openings on the sidewalls of the base portion. The showerhead further comprises a stem portion extending from the conical portion. The stem portion comprises a gas inlet. The conical portion comprises a plurality of bores in fluid communication with the gas inlet. The plurality of bores extend towards the base portion and have second openings on the sidewalls of the base portion above the first openings. The showerhead further comprises an annular sealing member is attached to the base portion below the first openings and to the conical portion above the second openings defining an annular volume in fluid communication with the plenum. The base portion comprises a plurality of through holes extending vertically from a bottom surface of the base portion to the plenum. The through holes are arranged interstitially with the pillars.

In additional features, the showerhead further comprises a stem portion extending from the conical portion. The conical portion comprises a plurality bores extending from the stem portion towards the base portion for receiving a plurality of heaters, respectively.

In additional features, the showerhead further comprises a stem portion extending from the conical portion. The conical portion comprises one or more bores extending from the stem portion towards the base portion for receiving one or more temperature sensors, respectively.

In additional features, the showerhead further comprises a stem portion extending from the conical portion. The stem portion comprises a gas inlet. The conical portion comprises a first plurality of bores in fluid communication with the gas inlet. The first plurality of bores extends towards the base portion and connects to the plenum. The conical portion comprises a second plurality of bores extending from the stem portion towards the base portion for receiving a plurality of heaters, respectively. The conical portion comprises one or more bores extending from the stem portion towards the base portion for receiving one or more temperature sensors, respectively. The first and second plurality of bores and the one or more bores are interstitial to each additional. The base portion comprises a plurality of through holes extending vertically from a bottom surface of the base portion to the plenum. The through holes are arranged interstitially with the pillars.

In additional features, the sets of bores have first openings on the sidewalls of the base portion, and the plurality of bores have second openings on the sidewalls of the base portion above the first openings. The showerhead further comprises an annular sealing member attached to the base portion below the first openings and to the conical portion above the second openings defining an annular volume in fluid communication with the plenum. The base portion comprises a plurality of through holes extending vertically from a bottom surface of the base portion to the plenum. The through holes are arranged interstitially with the pillars.

In additional features, the conical portion comprises a second plurality of bores extending from the stem portion towards the base portion for receiving a plurality of heaters, respectively. The conical portion comprises one or more bores extending from the stem portion towards the base portion for receiving one or more temperature sensors, respectively. The plurality of bores, the second plurality of bores, and the one or more bores are interstitial to each additional. The base portion comprises a plurality of through holes extending vertically from a bottom surface of the base portion to the plenum. The through holes are arranged interstitially with the pillars.

In additional features, the base portion comprises a plurality of through holes extending vertically from a bottom surface of the base portion to the plenum. The through holes are arranged interstitially with the pillars.

In additional features, the pillars are arranged in a first pattern. Each of the pillars is surrounded by a set of the through holes arranged in a second pattern.

In additional features, the first and second patterns are square patterns.

In additional features, a first set of the through holes is arranged in a first pattern in a first region of the base portion. A second set of the through holes is arranged in a second pattern in a second region of the base portion.

In additional features, the first and second regions are concentric.

In still other features, a showerhead comprises a base portion and a backplate having a different shape than the base portion extending from the base portion. The backplate and the base portion are monolithic. The showerhead comprises a first plurality of pillars arranged in a first plenum defined within sidewalls of the base portion. The first plurality of pillars extends vertically towards the backplate. The showerhead comprises a second plurality of pillars arranged in a second plenum defined within the sidewalls of the base portion above the first plenum. The second plurality of pillars extends vertically towards the backplate.

In additional features, the base portion is cylindrical. The backplate comprises a conical portion extending from the base portion. The conical portion and the base portion are monolithic.

In additional features, the second plurality of pillars are interstitial to the first plurality of pillars.

In additional features, the first and second plenums are disjoint.

In additional features, the base portion comprises first sets of bores extending across the base portion. The first sets of bores intersect each additional defining the first plurality of pillars at first intersections of the first sets of bores. The base portion comprises second sets of bores extending across the base portion above the first sets of bores. The second sets of bores intersect each additional defining the second plurality of pillars at second intersections of the second sets of bores.

In additional features, the first sets of bores have first openings on the sidewalls of the base portion. The second sets of bores have second openings on the sidewalls of the base portion above the first openings. The showerhead further comprises a stem portion extending from the conical portion. The stem portion comprises a first gas inlet and a second gas inlet. The conical portion comprises a first bore in fluid communication with the second gas inlet. The first bore extends from the stem portion through the conical portion into the second plenum. The conical portion comprises a second bore in fluid communication with the first gas inlet. The second bore extends from the stem portion into the conical portion. The conical portion comprises a plurality of bores extending from a distal end of the second bore towards the base portion and having third openings on the sidewalls of the base portion. The third openings are above the first and second openings. The showerhead further comprises a first annular sealing member attached to the base portion below the first and second openings and to the conical portion above the third openings defining an annular volume in fluid communication with the first plenum. The showerhead further comprises a second annular sealing member attached to the sidewalls of the base portion closing the first and second openings and separating the second plenum from the first plenum. The base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the showerhead further comprises a stem portion extending from the conical portion. The conical portion comprises a plurality of bores extending from the stem portion towards the base portion for receiving a plurality of heaters, respectively.

In additional features, the showerhead further comprises a stem portion extending from the conical portion. The conical portion comprises one or more bores extending from the stem portion towards the base portion for receiving one or more temperature sensors, respectively.

In additional features, the conical portion comprises a second plurality of bores extending from the stem portion towards the base portion for receiving a plurality of heaters, respectively. The conical portion comprises one or more bores extending from the stem portion towards the base portion for receiving one or more temperature sensors, respectively. The plurality of bores, the second plurality of bores, and the one or more bores are interstitial to each additional. The base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the first plurality of pillars is arranged in a first pattern. Each of the first plurality of pillars is surrounded by the first plurality of through holes arranged in a second pattern.

In additional features, the first and second patterns are square patterns.

In additional features, the second plurality of pillars and the second plurality of through holes are arranged in a square pattern.

In additional features, a first set of the second plurality of through holes is arranged in a first pattern in a first region of the base portion. A second set of the second plurality of through holes is arranged in a second pattern in a second region of the base portion.

In additional features, the first and second regions are concentric.

In additional features, the first and second regions lie in different quadrants.

In additional features, the quadrants are adjacent.

In additional features, the quadrants are diagonally opposite to each additional.

In still other features, a showerhead comprises a base portion and a backplate having a different shape than the base portion extending from the base portion. The showerhead comprises a first plurality of pillars arranged in a first plenum defined between the base portion and the backplate within sidewalls of the base portion and the backplate. The first plurality of pillars extends vertically between the base portion and the backplate. The showerhead comprises a second plurality of pillars arranged in a second plenum defined above the first plenum within the sidewalls of the base portion and the backplate. The second plurality of pillars extends vertically towards the backplate.

In additional features, the base portion is cylindrical. The backplate comprises a cylindrical base and a conical portion. The cylindrical base is attached to the base portion. The conical portion extends from the cylindrical base. The first plenum is defined between an upper region of the base portion and a lower region of the cylindrical base within the sidewalls of the base portion and the cylindrical base. The first plurality of pillars extends vertically between the base portion and the cylindrical base. The second plenum is defined within the sidewalls of the base portion and the cylindrical base. The second plurality of pillars extend vertically towards the conical portion.

In additional features, the second plurality of pillars are interstitial to the first plurality of pillars.

In additional features, the first and second plenums are disjoint.

In additional features, the showerhead further comprises a metal plate sealingly attached to the upper region of the base portion and a bottom region of the cylindrical base. The metal plate separates the second plenum from the first plenum. The first and second plurality of pillars respectively contact bottom and upper surfaces of the metal plate.

In additional features, the base portion comprises a first recess in the upper region abutting the cylindrical base and comprises the first plurality of pillars that extend through the first recess towards the cylindrical base. The cylindrical base comprises a second recess in bottom region abutting the base portion and comprises the second plurality of pillars that extend through the second recess towards the base portion. The showerhead further comprises a metal plate sealingly attached to the upper region of the base portion and the bottom region of the cylindrical base. The metal plate contacts the first and second plurality of pillars.

In additional features, the base portion comprises a first recess in the upper region abutting the cylindrical base and comprises the first plurality of pillars that extend through the first recess towards the cylindrical base. The cylindrical base comprises a second recess in bottom region abutting the base portion. The showerhead further comprises a metal plate. The metal plate comprises the second plurality of pillars arranged on an upper surface of the metal plate. The metal plate sealingly attached to the upper region of the base portion and the bottom region of the cylindrical base. A bottom surface of the metal plate contacts the first plurality of pillars. The second plurality of pillars extends through the second recess and contacting the cylindrical base.

In additional features, the base portion comprises a first recess in the upper region abutting the cylindrical base. The cylindrical base comprises a second recess in bottom region abutting the base portion. The showerhead further comprises a metal plate sealingly attached to the upper region of the base portion and the bottom region of the cylindrical base. The metal plate comprises the first and second plurality of pillars respectively arranged on bottom and top surfaces of the metal plate. The first plurality of pillars extends through the first recess towards the base portion and contacts the base portion. The second plurality of pillars extends through the second recess towards the cylindrical base and contacts the cylindrical base.

In additional features, the showerhead further comprises a stem portion attached to the conical portion of the backplate. The stem portion comprises a first gas inlet and a second gas inlet. The backplate comprises a first bore in fluid communication with the second gas inlet, the first bore extending from the stem portion through the conical portion into the second plenum. The backplate comprises a second bore in fluid communication with the first gas inlet, the second bore extending from the stem portion into the conical portion. The backplate comprises a plurality of bores extending from a distal end of the second bore towards the base portion and connecting to the first plenum. The base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the showerhead further comprises a stem portion attached to the conical portion of the backplate. The backplate comprises a plurality of bores extending from the stem portion towards the base portion for receiving a plurality of heaters, respectively.

In additional features, the showerhead further comprises a stem portion attached to the conical portion of the backplate. The backplate comprises one or more bores extending from the stem portion towards the base portion for receiving one or more temperature sensors, respectively.

In additional features, the backplate comprises a second plurality of bores extending from the stem portion towards the base portion for receiving a plurality of heaters, respectively. The backplate comprises one or more bores extending from the stem portion towards the base portion for receiving one or more temperature sensors, respectively. The plurality of bores, the second plurality of bores, and the one or more bores are interstitial to each additional. The base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars to the second plenum. The second plurality of through holes is arranged interstitially with the second plurality of pillars.

In additional features, the first plurality of pillars is arranged in a first pattern. Each of the first plurality of pillars is surrounded by the first plurality of through holes arranged in a second pattern.

In additional features, the first and second patterns are hexagonal.

In additional features, the second plurality of pillars and the second plurality of through holes are arranged in a hexagonal pattern.

In additional features, the base portion comprises a first plurality of through holes extending vertically from a bottom surface of the base portion to the first plenum. The first plurality of through holes is arranged interstitially with the first plurality of pillars. The base portion comprises a second plurality of through holes extending vertically from the bottom surface of the base portion through the first plurality of pillars and the metal plate to the second plenum. The second plurality of through holes is arranged interstitially with the second plurality of pillars.

In additional features, diameters of the base portion and the cylindrical base are equal.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A shows an example of a substrate processing system that uses a single plenum showerhead in a processing chamber;

FIG. 1B shows an example of a substrate processing system that uses a dual plenum showerhead in a processing chamber;

FIG. 2 shows a side view of a first single plenum showerhead used in the processing chamber of FIG. 1A;

FIG. 3 shows a top view of the first showerhead of FIG. 2;

FIG. 4 shows a cross-sectional view of a base portion of the first showerhead of FIG. 2 showing the plenum of the first showerhead of FIG. 2;

FIG. 5 shows an example of a pattern of pillars and through holes in the plenum of the first showerhead of FIG. 2;

FIG. 6 shows a cross-sectional view of the first showerhead of FIG. 2 showing heater bores of the first showerhead of FIG. 2;

FIG. 7A shows a cross-sectional view of the first showerhead of FIG. 2 showing bores for flowing process gases through the plenum of the first showerhead of FIG. 2;

FIG. 7B shows a side view of the base portion and cylindrical base of the backplate of the first showerhead of FIG. 2 showing an alternate way to form the plenum of the first showerhead of FIG. 2;

FIG. 8 shows a cross-sectional view of the first showerhead of FIG. 2 showing a bore for a temperature sensor used in the first showerhead of FIG. 2;

FIG. 9 shows a side view of a second single plenum showerhead used in the processing chamber of FIG. 1A;

FIG. 10 shows a top view of the second showerhead of FIG. 9;

FIG. 11 shows a cross-sectional view of the second showerhead of FIG. 9 showing the plenum and bores for flowing process gases through the second showerhead of FIG. 9;

FIG. 12 shows a cross-sectional view of the second showerhead of FIG. 9 showing a bore for a temperature sensor used in the second showerhead of FIG. 9;

FIG. 13 shows a cross-sectional view of the second showerhead of FIG. 9 showing heater bores of the second showerhead of FIG. 9;

FIG. 14A shows a cross-sectional view of a base portion of the second showerhead of FIG. 9 showing the plenum of the second showerhead of FIG. 9;

FIG. 14B shows an example of a pattern of pillars and through holes in the plenum of the second showerhead of FIG. 9;

FIG. 15 shows a cross-sectional view of the base portion of the second showerhead of FIG. 9 showing a section of top of the plenum of the second showerhead of FIG. 9;

FIG. 16 shows a bottom view of the second showerhead of FIG. 9 showing an example of a pattern of through holes of the second showerhead of FIG. 9;

FIGS. 17 and 18 shows additional examples of patterns in which the through holes of the second showerhead of FIG. 9 can be arranged;

FIG. 19 shows a top view of a ring attached to the cylindrical base and the base portion of the second showerhead of FIG. 9;

FIG. 20 shows a cross-sectional view of the ring attached to the cylindrical base and the base portion of the second showerhead of FIG. 9;

FIG. 21 shows a cross-sectional view of the second showerhead of FIG. 9 similar to FIG. 11 showing the bores for flowing process gases and the ring of FIG. 20;

FIG. 22 shows a side view of a third showerhead, which is a dual plenum showerhead, used in the processing chamber of FIG. 1B;

FIG. 23 shows a top view of the third showerhead of FIG. 22;

FIG. 24A shows a cross-sectional view of the third showerhead of FIG. 22 showing the dual plenums and bores for flowing process gases through the third showerhead of FIG. 22;

FIG. 24B shows a side view of a base portion of the third showerhead of FIG. 22 showing the dual plenums, specifically a second plenum stacked on a first plenum in the base portion;

FIG. 24C shows the side view of the base portion of the third showerhead of FIG. 22 showing a ring around the second plenum;

FIG. 24D shows a cross-sectional view of the base portion of the third showerhead of FIG. 22 showing the second plenum;

FIG. 24E shows an example of a pattern of pillars and through holes in the second plenum of the third showerhead of FIG. 22;

FIG. 25 shows a cross-sectional view of the third showerhead of FIG. 22 showing a bore for a temperature sensor used in the third showerhead of FIG. 22;

FIG. 26 shows a cross-sectional view of the third showerhead of FIG. 22 showing heater bores of the third showerhead of FIG. 22;

FIG. 27A shows a cross-sectional view of the base portion of the third showerhead of FIG. 22 showing a first example of the first plenum of the third showerhead of FIG. 22;

FIGS. 27B and 27C show an example of a pattern of pillars and through holes in the first example of first plenum of the third showerhead of FIG. 22;

FIG. 28A shows a cross-sectional view of the base portion of the third showerhead of FIG. 22 showing a second example of the first plenum of the third showerhead of FIG. 22;

FIGS. 28B and 28C show an example of a pattern of pillars and through holes in the second example of first plenum of the third showerhead of FIG. 22;

FIG. 29 shows a top cross-sectional view of an example of a layout of the through holes of the second plenum relative to the pillars of the first plenum;

FIGS. 30-37 show various examples of patterns in which the through holes of the second plenum can be arranged;

FIGS. 38 and 39 show examples of patterns in which the through holes of the first plenum can be arranged;

FIG. 40 shows a cross-sectional view of the third showerhead of FIG. 9 similar to FIG. 24A showing the bores for flowing process gases and a ring around the first plenum similar to that shown in FIG. 21;

FIG. 41 shows a side view of a fourth dual plenum showerhead, which is a dual plenum showerhead, used in the processing chamber of FIG. 1B;

FIG. 42 shows a top view of the fourth showerhead of FIG. 41;

FIG. 43A shows a cross-sectional view of the fourth showerhead of FIG. 41 showing the dual plenums and bores for flowing process gases through the fourth showerhead of FIG. 41;

FIG. 43B shows a side view of a cylindrical base of a backplate of the fourth showerhead of FIG. 41 showing a first example of forming the second plenum in the cylindrical base of the backplate of the fourth showerhead of FIG. 41;

FIG. 43C shows a side view of the cylindrical base of the backplate of the fourth showerhead of FIG. 41 showing a second example of forming the second plenum in the cylindrical base of the backplate of the fourth showerhead of FIG. 41;

FIG. 43D shows a side view of the base portion and cylindrical base of the backplate of the fourth showerhead of FIG. 41 showing an alternate way to form the dual plenums of the fourth showerhead of FIG. 41;

FIG. 44 shows a cross-sectional view of a base portion of the fourth showerhead of FIG. 41 showing the first plenum of the fourth showerhead of FIG. 41;

FIG. 45 shows an example of a pattern of pillars and through holes in the first plenum of the fourth showerhead of FIG. 41;

FIG. 46 shows a cross-sectional view of the second plenum of the fourth showerhead of FIG. 41 showing a layout of pillars and through holes of the second plenum;

FIG. 47 shows an example of a pattern of the pillars and the through holes in the second plenum of the fourth showerhead of FIG. 41;

FIG. 48 shows a cross-sectional view of the fourth showerhead of FIG. 41 showing heater bores of the fourth showerhead of FIG. 41; and

FIG. 49 shows a cross-sectional view of the fourth showerhead of FIG. 41 showing a bore for a temperature sensor used in the fourth showerhead of FIG. 41.

In the drawings, reference numbers may be reused to identify similar and/or identical elements.

### DETAILED DESCRIPTION

Demand for improving film properties and deposition rates in plasma enhanced chemical vapor deposition (PECVD) and atomic layer deposition (ALD) equipment is increasing. The increasing demand is driving requirements for higher radio frequency (RF) power and faceplate temperatures for showerheads. The higher RF power and faceplate temperatures for the showerheads create two interrelated problems. First, a higher heat flow through the showerhead increases temperature gradients within the showerhead. The temperature gradients increase thermomechanical stresses in the showerhead due to differential thermal expansion of the showerhead. Second, the higher showerhead faceplate temperatures reduce yield strength and viscoelastic creep modulus of structural materials of the showerhead. Thermo-elastic stresses cause higher plastic strains and higher creep rates in the showerhead. In combination, these effects lead to progressive deformation of the showerhead with each thermal cycle. The deformation locally alters a process gap (i.e., a gap between the faceplate and the substrate), which perturbs the deposition process.

Both of these effects are amplified by the typical construction of a PECVD/ALD showerhead. In the typical showerhead, a disc-shaped faceplate is welded along its rim to a disc-shaped backplate above the disc-shaped faceplate. A cylindrical gas plenum is enclosed within the faceplate and the backplate. The gas plenum distributes process gases to an array of gas orifices in the faceplate. A heat sink is connected to an upper central (stem) region of the backplate. The gas plenum has negligible thermal conductivity. Therefore, the heat incident on the faceplate due to thermal radiation and/or interaction with an RF-generated plasma must flow radially outward within the faceplate. Then the heat must flow radially inward within the backplate to reach the heat sink. These radial heat flows create large and opposing radial temperature gradients in the faceplate and the backplate. The temperature gradients generate high thermomechanical stresses that may exceed a local yield strength. As a result, when used for a high-rate deposition of advanced hard mask films, these showerheads undergo rapid progressive plastic deformation. The deformation leads to process failures. The deformation also shortens the life of these showerheads.

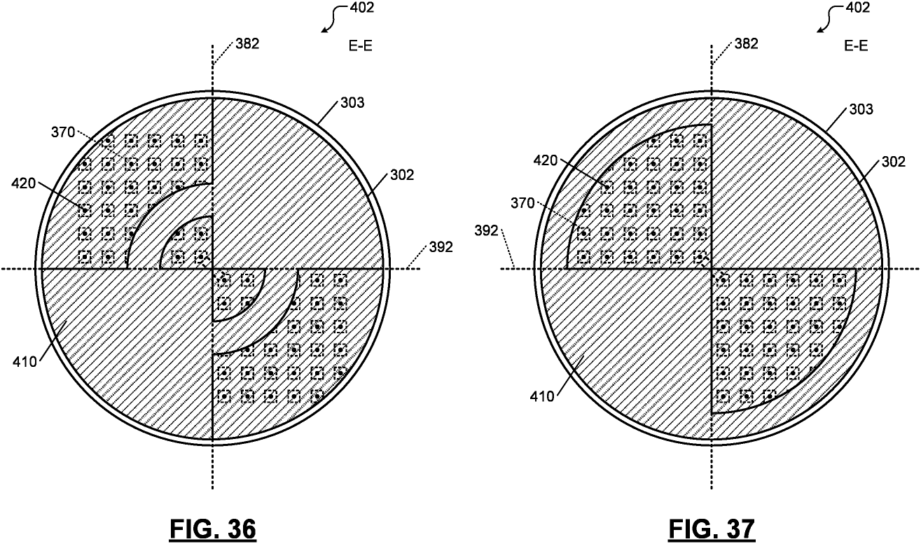

The present disclosure provides various showerhead designs that alleviate the above problems. Specifically, the showerheads of the present disclosure include a high-solidity plenum. The high-solidity plenum is a region between the faceplate and the backplate. The region combines high gas conductance in horizontal (i.e., radial) directions with high heat conduction in the vertical (i.e., axial) direction through a dense array of vertical pillars. The array of pillars solves the problem of temperature gradients in two ways. First, a high heat conduction in the vertical direction through the pillars causes the radial temperature gradients above and below the plenum to be closely similar rather than opposing. The closely similar radial temperature gradients largely eliminates the source of deformational thermomechanical stresses. Second, any remaining deformational loads are distributed across the many pillars. The distribution of the deformational loads further reduces the stresses. In addition, each of the showerheads of the present disclosure comprisesa conical backplate made of solid metal. The stem of the showerhead is connected to the apex of the conical backplate. The conical backplate further helps in conducting heat from the faceplate to the heat sink located at the stem of the showerhead. The following is a brief summary of various showerhead designs according to the present disclosure. The showerhead designs are described in detail with references to FIGS. 2-49.

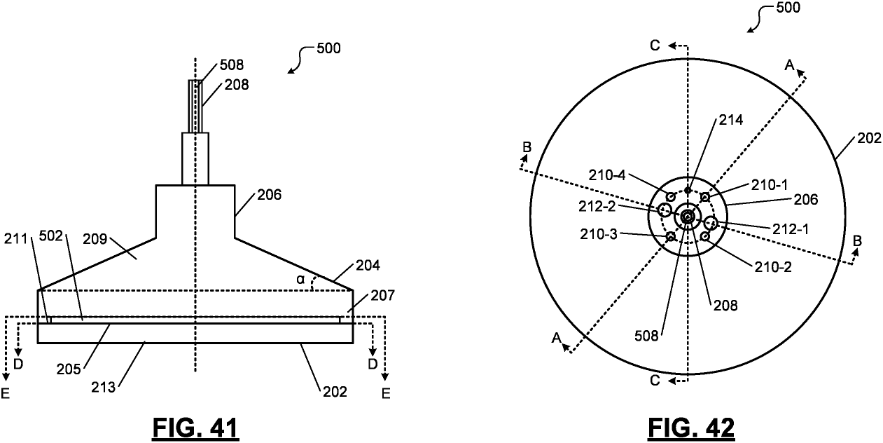

In an example, shown and described in detail with reference to FIGS. 2-8, the showerhead is manufactured from a stack of two or more metal plates joined together by diffusion welding. The pillars are defined by removing material from (e.g., by machining) one or both plates bounding a plenum volume. The pillars are arranged so as to not interfere with gas orifices in the lowermost plate. For example, the pillars are arranged in a pattern that is interstitial to a gas orifice pattern. Alternatively, the plates are joined by diffusion brazing or another furnace brazing process rather than by diffusion welding. A showerhead manufactured in this manner may include more than one such plenum. For example, a stack of three plates can be used to bound two plenums arranged one above the other. An upper plenum distributes gas to channels passing vertically through the pillars in a lower plenum to gas orifices arranged interstitially to those fed by the lower plenum. An example of such as dual plenum showerhead is shown and described with reference to FIGS. 41-49. The same principle can be used to provide three or more plenums arranged vertically. Any plenum bounded by two such plates may be subdivided by vertical walls into multiple coplanar plenums, for example, in concentric radial zones, azimuthal zones, or a combination of these. In some examples, one or more of the plates can be formed to net shape by processes such as forging, die casting, upsetting, thixo-molding, or metal injection molding. In other examples, one or more of the plates can be manufactured by an additive manufacturing process such as powder bed fusion, transfer welding, direct energy deposition, or electron-beam freeform fabrication.

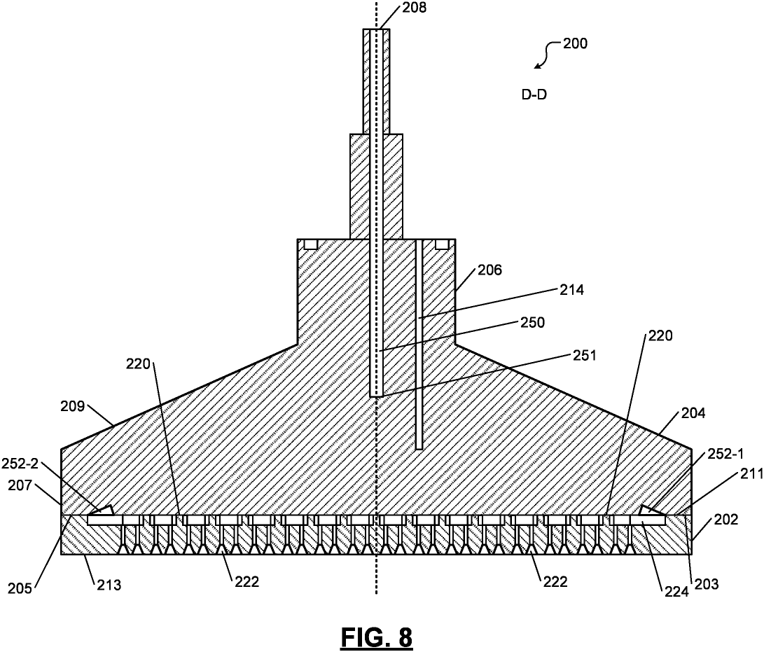

In another example, shown and described in detail with reference to FIGS. 9-21, the plenum comprises intersecting linear arrays of bores lying in a horizontal plane (i.e., parallel to the faceplate). The pillars comprise the material remaining between bores, which are machined cylindrical features having a large length-to-diameter ratio such as in deep/gun drillings. The bores may lie along two orthogonal directions, two non-orthogonal directions, or three directions approximately 120° apart. The gas orifices are arrayed so as to intersect the axes of these bores. Each gas orifice may intersect a single bore, or lie within an intersection of two or three bores. A showerhead manufactured as described above may comprise more than one such intersecting-bore plenum. For example, two networks of bores may be arranged one above the other. An upper network of bores distributes gas to channels passing vertically through the pillars in a lower plenum to gas orifices. The gas orifices are arranged interstitially to those fed by a lower network of bores. An example of such as dual plenum showerhead is shown and described with reference to FIGS. 22-40. The same principle can be used to provide three or more plenums arranged vertically. Alternatively, the two or more networks may feed orifices in different concentric radial zones, azimuthal zones, or a combination of these.

The fabrication processes used to manufacture an intersecting-bore plenum, such as deep-hole drilling cause the bores to extend to the edges of the workpiece. The resulting open ends of the bores can be enclosed to prevent process gases from escaping. For example, a ring can be attached to the circumference of the workpiece to form a gas-tight (i.e., sealing) boundary. Such a ring may be fabricated using any of several processes including milling, lathe turning, forging, stamping, drawing, spinning, die casting, thixo-molding, metal injection molding, powder bed fusion, transfer welding, or electron-beam freeform fabrication. The ring may be attached to the circumference of the workpiece using a process such as welding, brazing, threading, upsetting, swaging, interference fitting, or shrink fitting. Alternatively, each open bore end may be closed by an individual plug. Such plugs may be fabricated by any of the previously mentioned fabrication processes, for example by drawing or by turning on a screw machine. The plugs can be attached using any of the previously mentioned attachment processes, for example by threading, upsetting, interference fitting, or shrink fitting.

The showerheads designed according to the present disclosure provide the following advantages over prior art showerheads. The showerheads have a lower rate of progressive thermomechanical deformation, which translates into a longer lifetime before process failure can occur. The showerheads can tolerate a higher faceplate heat flux or temperature, which allows higher deposition rates, higher wafer throughput, and/or provide better properties to the deposited film. The showerheads have a smaller radial temperature gradient in the faceplate, which reduces the radial non-uniformity of properties in the deposited film. The radial temperature gradient is edge-hot (rather than center-hot), which reduces the radial non-uniformity of properties in the deposited film. The reduction occurs because the edge-hot radial temperature gradient helps to offset the undesirably higher radiative heat loss from the near-edge region of the wafer to sidewalls of the processing chamber. These and other features of the showerheads are described below in detail.

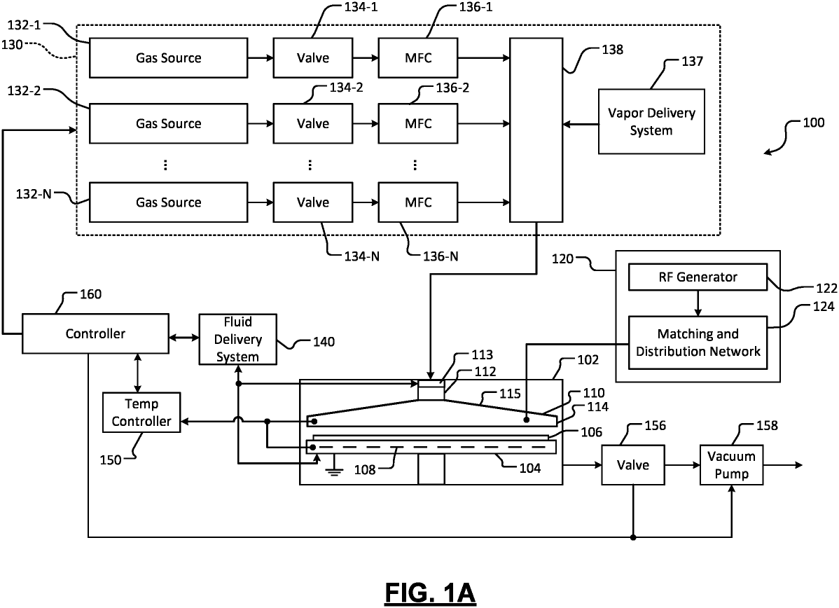

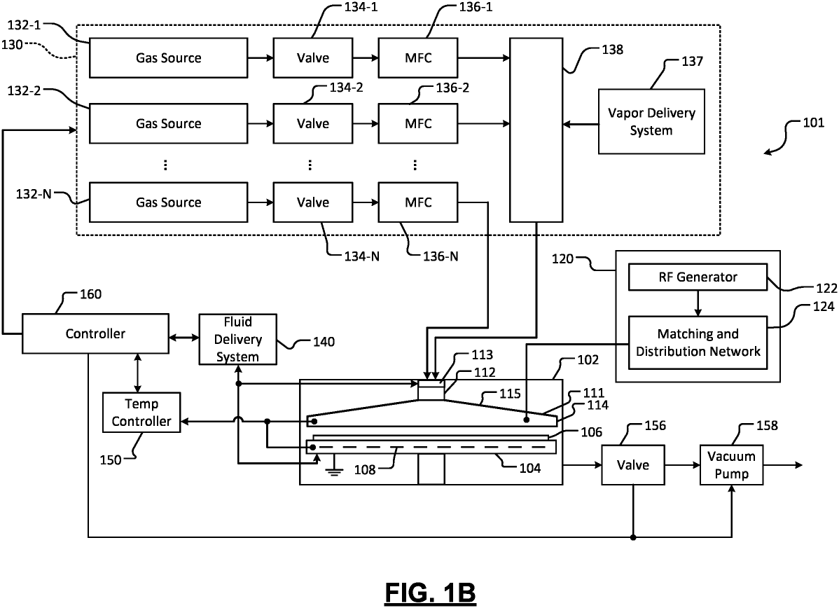

The present disclosure is organized as follows. Before describing the showerhead designs, examples of substrate processing systems in which the showerheads can be used are shown and described with reference to FIGS. 1A and 1B. Thereafter the first, second, third, and fourth showerheads are shown and described with reference to FIGS. 2-8, FIGS. 9-21, FIGS. 22-40, and FIGS. 41-49, respectively.

### Examples of Substrate Processing Systems

FIG. 1A shows an example of a substrate processing system 100 comprising a processing chamber 102 configured to process a substrate using processes such as PECVD or thermal ALD (T-ALD). The processing chamber 102 encloses other components of the substrate processing system 100. The processing chamber 102 comprises a substrate support (e.g., a pedestal) 104. During processing, a substrate 106 is arranged on the pedestal 104.

One or more heaters 108 (e.g., a heater array) may be disposed in a ceramic plate arranged on a metallic baseplate of the pedestal 104 to heat the substrate 106 during processing. One or more additional heaters called zone heaters or primary heaters (not shown) may be arranged in the ceramic plate above or below the heaters 108. Additionally, while not shown, a cooling system comprising cooling channels through which a coolant can flow to cool the pedestal 104 may be disposed in the baseplate of the pedestal 104. Additionally, while not shown, one or more temperature sensors may be disposed in the pedestal 104 to sense the temperature of the pedestal 104.

The processing chamber 102 comprises a gas distribution device 110 such as a showerhead to introduce and distribute process gases into the processing chamber 102. The gas distribution device (hereinafter showerhead) 110 is made of a metal such as aluminum or an alloy and is a chandelier style showerhead. The showerhead 110 can include any of the showerheads shown in FIGS. 2-21 and is described in further detail with reference to FIGS. 2-21.

Briefly, the showerhead 110 comprises a base portion 114 and a backplate 115. The base portion 114 is cylindrical. A substrate-facing surface of the base portion 114 is called a faceplate (shown in subsequent figures). The faceplate comprises a plurality of outlets or features (e.g., slots or through holes collectively called orifices) through which precursors flow into the processing chamber 102. The backplate 115 is conical, made of solid metal, and extends upwards from the base portion 114. The backplate 115 comprises heaters, temperature sensors, and bores for supplying process gases, all of which are shown in subsequent figures.

The showerhead 110 further comprises a cylindrical stem portion 112. A first end of the stem portion 112 is connected to an apex of the conus of the backplate 115. A second end of the stem portion 112 is connected to a top plate of the processing chamber 102. A heat sink 113 is connected to the second end of the stem portion 112. For example, the heat sink 113 may include cooling channels through which a coolant (e.g., water) is circulated. The backplate 115 conducts heat from the base portion 114. The heat sink 113 removes heat from the backplate 115.

If plasma is used, the substrate processing system 100 may include an RF generating system (or an RF source) 120 that generates and outputs an RF voltage. The RF voltage may be applied to the showerhead 110, and the pedestal 104 can be DC grounded, AC grounded, or floating as shown. Alternatively, while not shown, the RF voltage can be applied to the pedestal 104, and the showerhead 110 may be DC grounded, AC grounded, or floating. For example, the RF generating system 120 may include an RF generator 122 that generates RF power. The RF power is fed by a matching and distribution network 124 to the showerhead 110 or the pedestal 104. In other examples, while not shown, the plasma may be generated inductively or remotely and then supplied to the processing chamber 102.

A gas delivery system 130 comprises gas sources 132-1, 132-2, ..., and 132-N (collectively, the gas sources 132), where N is a positive integer. The gas delivery system 130 comprises valves 134-1, 134-2, ..., and 134-N (collectively, the valves 134). The gas delivery system 130 comprises mass flow controllers 136-1, 136-2, ..., and 136-N (collectively, the mass flow controllers 136). The gas sources 132 are connected by the valves 134 and the mass flow controllers 136 to a manifold 138. In some processes, a vapor delivery system 137 supplies vaporized precursors to the manifold 138. An output of the manifold 138 is fed to the showerhead 110. The gas sources 132 may supply process gases, cleaning gases, purge gases, inert gases, and so on to the processing chamber 102.

A fluid delivery system 140 supplies a coolant to the cooling system in the pedestal 104 and to the heat sink 113 of the showerhead 110. A temperature controller 150 may be connected to the heaters 108, the zone heaters, the cooling system, and the temperature sensors in the pedestal 104. The temperature controller 150 may also be connected to the heat sink 113 and to the heaters and the temperature sensors in the showerhead 110. The temperature controller 150 may control power supplied to the heaters 108, the zone heaters, and coolant flow through the cooling system in the pedestal 104 to control the temperature of the pedestal 104 and the substrate 106. The temperature controller 150 may also control power supplied to the heaters disposed in the showerhead 110 and coolant flow through the heat sink 113 of the showerhead 110 to control the temperature of the showerhead 110.

A vacuum pump 158 can maintain sub-atmospheric pressure inside the processing chamber 102 during substrate processing. A valve 156 is connected to an exhaust port of the processing chamber 102. The valve 156 and the vacuum pump 158 are used to control pressure in the processing chamber 102. The valve 156 and the vacuum pump 158 are used to evacuate reactants from the processing chamber 102 via the valve 156. A system controller 160 controls the components of the substrate processing system 100.

FIG. 1B shows an example of a substrate processing system 101 that is identical to the substrate processing system 100 except for the following differences. The substrate processing system 101 comprises a dual plenum showerhead 111. The dual plenum showerhead 111 is also a chandelier type showerhead. The dual plenum showerhead 111 can include any of the showerheads shown in FIGS. 22-49. The dual plenum showerhead 111 is described in further detail with reference to FIGS. 22-49. One set of the gas sources 132, valves 134, and MFCs 136 supplies a second gas to a second plenum of the dual plenum showerhead 111. The description of other elements of the substrate processing system 101 having identical reference numbers as those shown in FIG. 1A is not repeated for brevity.

The showerheads according to the present disclosure are now described in detail. Initially, two types of showerheads are disclosed: First, a showerhead having two distinct (i.e., separate) metallic elements - a faceplate and a backplate (shown in FIGS. 2-8); and second, a monolithic showerhead with the faceplate and the backplate manufactured from a single piece of metal (shown in FIGS. 9-21). Subsequently, two dual plenum showerheads are shown and described with reference to FIGS. 22-49.

Each showerhead is now described with reference to respective sets of figures, which show various views of the respective showerheads. During the description of each showerhead, while each view is described with reference to a particular figure, in the description of each figure, other figures from the set of figures for that showerhead and other showerheads are referenced as needed to aid the discussion. This is because an element being described with reference to a figure may be better seen in another referenced figure.

Each showerhead described below can be made of a solid metallic material (i.e., the showerheads are not hollow except for the bores and plenums described below). While the base portions of the showerheads are shown and described as being cylindrical in shape, the base portions can be in the form of a conical frustum instead, with the backplate extending from the top of the conical frustum. Accordingly, the base portions can be considered as being substantially cylindrical in shape. Similarly, the cylindrical bases of the backplates are shown and described as being cylindrical in shape. However, the cylindrical bases of the backplates can also be in the form of a conical frustum instead, with the conical portion of the backplate extending from the top of the conical frustum. Accordingly, the cylindrical bases of the backplates can also be considered as being substantially cylindrical in shape. Further, the backplates of the showerheads are shown and described as being conical in shape. However, the conical shape of the backplates can include compound curvature. Accordingly, the backplates can be considered as being substantially conical in shape.

### First Showerhead (Single Plenum, Non-Monolithic)

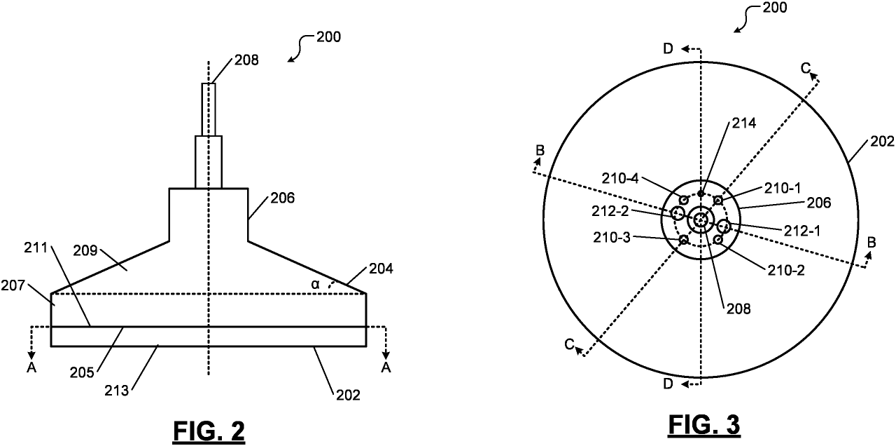

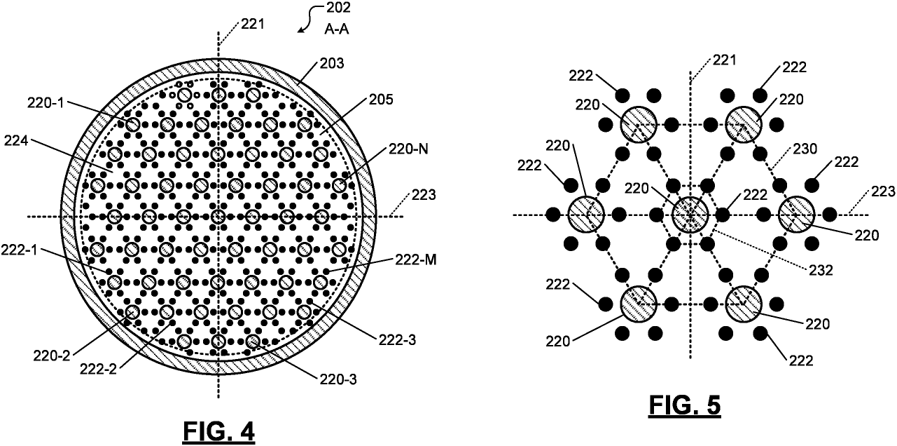

FIGS. 2-8 show various views of a first showerhead 200. FIG. 2 shows a side view of the showerhead 200. FIG. 3 shows a top view of the showerhead 200. FIGS. 4-8 show various cross-sectional views of the showerhead 200. Each cross-sectional view shows different features of the showerhead 200.

In FIG. 2, the showerhead 200 comprises a base portion 202, a backplate 204, and a stem portion 206. The base portion 202 is cylindrical. The base portion 202 is described in further detail with reference to FIGS. 4 and 5. The backplate 204 has a cylindrical base 207 that is attached (i.e., joined) to the base portion 202 using one or more manufacturing processes described above.

The backplate 204 has a conical portion 209. The conical portion 209 extends upwards from the cylindrical base 207. The conical portion 209 attaches to the stem portion 206. The backplate 204 is a separate element than the base portion 202. The cylindrical base 207 and the conical portion 209 of the backplate 204 are integral (i.e., the backplate 204 is a single piece). The backplate 204 and the stem portion 206 can be separate pieces joined together or can also be integral (i.e., a single piece).

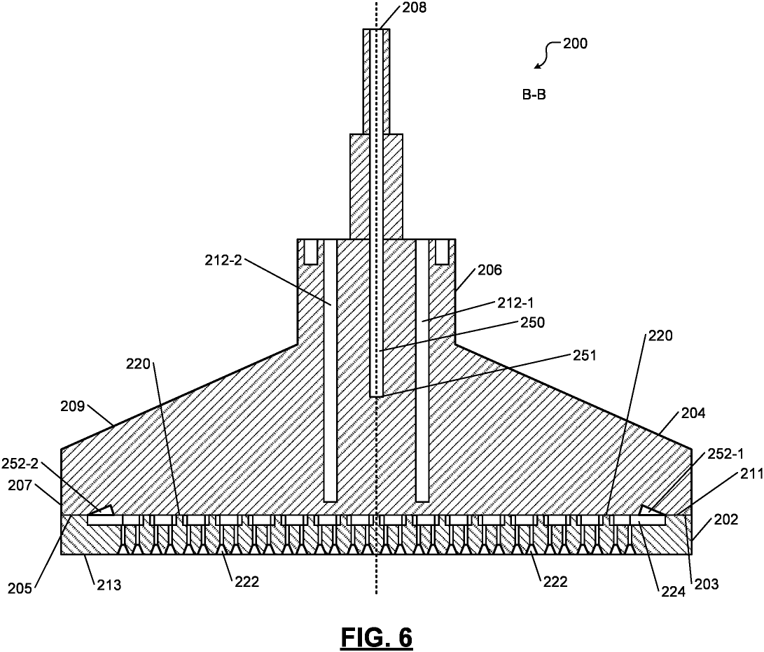

The backplate 204 is solid (i.e., is not hollow). The backplate 204 helps conduct heat from the base portion 202 to the heat sink 113 shown in FIG. 1A. The conical portion 209 slants relative to the cylindrical base 207 at an angle α. The angle α determines the volume of the conical portion 209. The angle α determines the heat conduction through the backplate 204. The angle α determines the weight of the showerhead 200. Greater volume of the conical portion 209 is desirable to conduct more heat. However, the angle α is selected so as to balance the heat conduction through the backplate 204 and the weight of the showerhead 200. For example, the angle α is about 45° but can be between 10° and 60°. The backplate 204 is described in further detail with reference to FIGS. 6-9.

A gas inlet 208 is provided in the center of the stem portion 206. The gas inlet 208 receives process gases from the gas delivery system 130 shown in FIG. 1A. The internal structure of the showerhead 200 including a plenum and bores for heaters, gas supply, and temperature sensors is shown and described in detail with reference to FIGS. 4-9.

FIG. 3 shows a top view of the showerhead 200. The stem portion 206 comprises bores 210-1, 210-2, 210-3, and 210-4 (collectively, the bores 210). The bores 210 receive fasteners (not shown) used to attach the showerhead 200 to the top plate of the processing chamber 102 shown in FIG. 1A. The stem portion 206 comprises bores 212-1 and 212-2 (collectively, the bores 212). Heaters are disposed through the bores 212 into the backplate 204 as shown in FIG. 6. The stem portion 206 comprises a bore 214 through which a temperature sensor (e.g., a thermocouple) is disposed into the backplate 204 as shown in FIG. 8.

Various cross-sections of the showerhead 200 are identified in FIGS. 2 and 3. These cross-sections are shown in FIGS. 4-9 and are used to describe the internal structure of the showerhead 200 including the plenum and the bores for heaters, gas supply, and temperature sensors in further detail.

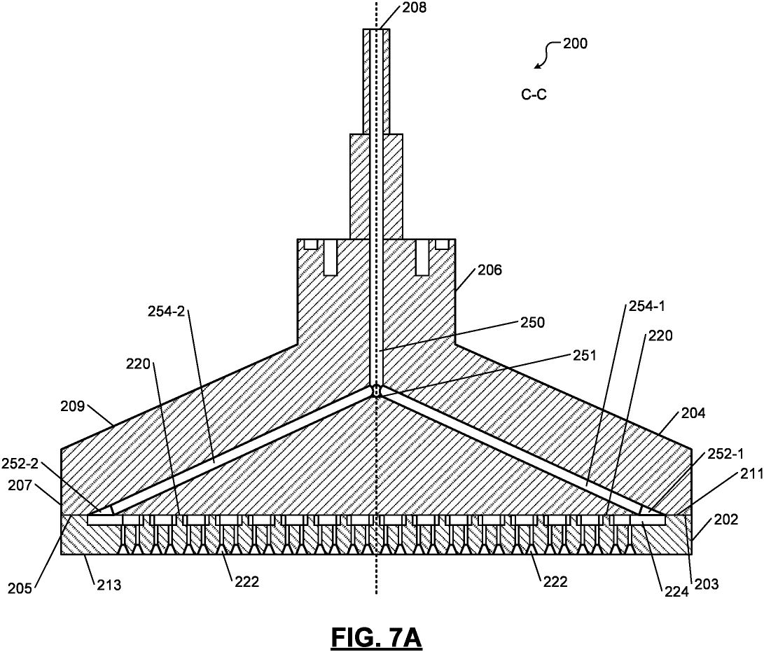

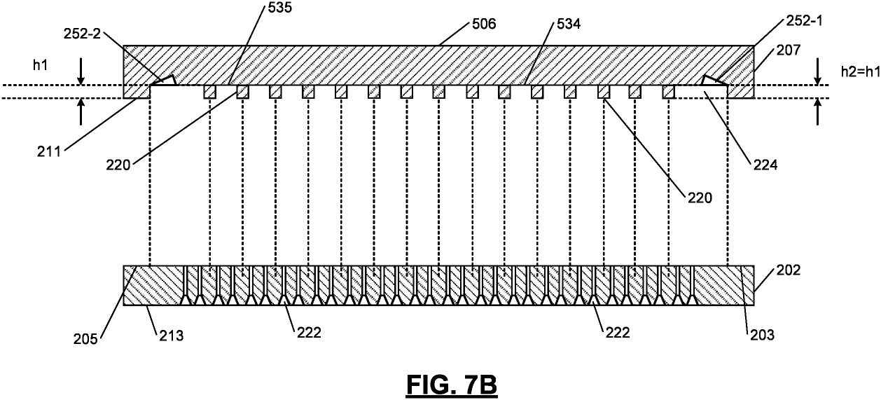

FIG. 4 shows a top view of a cross-section of the base portion 202 of the showerhead 200 taken along lines A-A shown in FIG. 2. The cross-section A-A shows a plenum 224 formed in the base portion 202 in detail. Another example of the plenum 224 is shown and described with reference to FIG. 7B.

In FIG. 4, the base portion 202 comprises a plurality of pillars 220-1, 220-2, 220-3, ..., and 220-N (collectively, the pillars 220), where N is a positive integer. The pillars 220 are formed by removing (e.g., machining) material from a top surface 205 of the base portion 202, which abuts a bottom surface 211 of the cylindrical base 207 of the backplate 204. The material is removed from the top surface 205 of the base portion 202 from the center of the base portion 202 to an inner diameter (ID) of a rim 203 of the base portion 202. The pillars 220 are solid (i.e., are not hollow). The pillars 220 extend vertically upwards towards the bottom surface 211 of the cylindrical base 207 of the backplate 204. The pillars 220 contact the bottom surface 211 of the cylindrical base 207 of the backplate 204.

The pillars 220 extend along an axis perpendicular to a plane in which the base portion 202 lies (hereinafter called the vertical axis of the showerhead 200). The vertical axis is perpendicular to the diameter of the base portion 202. The plane in which the base portion 202 lies is parallel to a plane in which the substrate 106 and a top surface of the pedestal 104 on which the substrate 106 is arranged. Accordingly, the vertical axis is also perpendicular to the plane of the substrate 106 and the top surface of the pedestal 104.

The pillars 220 are shown as being circular in shape for example only. Alternatively, the pillars 220 can be of any other polygonal or non-polygonal shape. Further, all of the pillars 220 need not have the same shape and/or size. The pillars 220 can have different shapes. For example, some of the pillars 220 can be circular while others can be hexagonal. The pillars 220 can have different diameters.

The pillars 220 are distributed from the center of the base portion 202 to the ID of the rim 203 of the base portion 202. The pillars 220 lie in a plane parallel to the diameter of the base portion 202 and perpendicular to the vertical axis of the shower head 200. The pillars 220 are distributed along first and second axes 221 and 223. The first and second axes 221 and 223 are perpendicular to each other. The first and second axes 221 and 223 are parallel to the diameter of the base portion 202. The pillars 220 conduct heat from a bottom surface 213 of the base portion 202 to the bottom surface 211 of the cylindrical base 207 of the backplate 204. The backplate 204 conducts the heat from the base portion 202 to the heat sink 113 shown in FIG. 1A. The pillars 220 conduct the heat along the vertical axis, which reduces radial temperature gradients across the base portion 202 and the backplate 204.

The top surface 205 of the base portion 202 is attached (i.e., joined) to the bottom surface 211 of the cylindrical base 207 of the backplate 204 at the peripheries of the base portion 202 and the backplate 204. Specifically, the rim 203 of the base portion 202 is attached (i.e., joined) to the rim of the bottom surface 211 of the cylindrical base 207 of the backplate 204. The top surface 205 of the base portion 202, the pillars 220, and the bottom surface 211 of the cylindrical base 207 of the backplate 204 define the plenum 224 of the showerhead 200. The plenum 224 is cylindrical. The plenum 224 extends from the center of the base portion to the ID of the rim 203 of the base portion 202. The plenum 224 has the same diameter as the ID of the rim 203 of the base portion 202.

The pillars 220 extend vertically upwards from the base portion 202 through the plenum 224. The pillars 220 contact the bottom surface 211 of the cylindrical base 207 of the backplate 204. The pillars 220 reduce the volume (i.e., cavity or hollowness) of the plenum 224. In other words, the pillars 220 provide solidity to the plenum 224. For example, the pillars 220 fill about 10% of the volume of the plenum 224. The amount of heat conducted by the pillars 220 from the bottom surface 213 of the base portion 202 to the bottom surface 211 of the backplate 204 is directly proportional to a density of the pillars 220. The density of the pillars 220 is the number of pillars 220 per unit area of the base portion 202 in the plenum 224. In other words, the amount of heat conducted by the pillars 220 is directly proportional to the number of pillars 220. The density of the pillars 220 is specified by requirements of processes performed on the substrate 106.

The base portion 202 comprises through holes (also called orifices) 222-1, 222-2, 222-3, ..., and 222-M (collectively, through holes 222), where M is an integer greater than N. The through holes 222 are drilled between the top surface 205 and the bottom surface 213 of the base portion 202 facing the substrate 106 shown in FIG. 1A. The through holes 222 are distributed around the pillars 220 from the center of the base portion 202 to the ID of the rim 203 of the base portion 202. The process gases received through the gas inlet 208 flow through a plurality of bores (shown in FIG. 7A) drilled in the backplate 204. The process gases flow through the plurality of bores into the plenum 224. The process gases exit the plenum 224 via the through holes 222 into the processing chamber 102 towards the substrate 106 shown in FIG. 1A.

FIG. 5 shows an example of a pattern in which the pillars 220 and the through holes 222 are arranged in the base portion 202. The pillars 220 are arranged interstitially relative to the through holes 222. The through holes 222 are arranged around the pillars 220. For example, the pillars 220 are arranged on vertices of a first hexagon 230. One pillar 220 lies at the center of the hexagon 230. For example, the through holes 222 are arranged around each pillar 220 on vertices of a second hexagon 232. The pattern of the pillars 220 and the through holes 222 extends from the center of the base portion 202 to the ID of the rim 203 of the base portion 202.

The pillars 220 and the through holes 222 can be arranged in other symmetric or asymmetric patterns. The patterns may depend on the requirements of processes performed on the substrate 106. The patterns are designed while maintaining a specified density of the pillars 220 in the plenum 224. The density of the pillars 220 in the plenum 224 determines the solidity of the plenum 224. The solidity of the plenum 224 determines the heat conduction through the base plate 202 to the backplate 204. The density of the pillars 220 is constrained by the requirements of the through holes 222 specified for the processes.

FIG. 6 shows a cross-section of the showerhead 200 taken along lines B-B shown in FIG. 3. The cross-section B-B shows a bore 250 that extends from the gas inlet 208 vertically downwards towards the base portion 202 through the stem portion 206. The bore 250 extends into the conical portion 209 of the backplate 204. The bore 250 extends through the center of the stem portion 206 and through the center of the conical portion 209 of the backplate 204 along the vertical axis of the showerhead 200. A distal end 251 of the bore 250 extends approximately half-way through the conical portion 209 of the backplate 204 as shown. Alternatively, the distal end 251 of the bore 250 can extend further up or down in the conical portion 209 of the backplate 204. From the distal end 251 of the bore 250, a plurality of bores (shown in FIG. 7A) extend laterally outwards and downwards through the conical portion 209 of the backplate 204. These bores connect to the plenum 224 in the base portion 202 at 252-1 and 252-2. These bores supply process gases from the gas inlet 208 to the plenum 224 as shown and described with reference to FIG. 7A.

The cross-section B-B shows the bores 212 for the heaters in detail. The bores 212 extend vertically downwards through the stem portion 206 and the conical portion 209 of the backplate 204. The bores 212 extend towards the base portion 202 along the vertical axis of the showerhead 200. The bores 212 extend into the cylindrical base 207 of the backplate 204 but do not extend to the bottom surface 211 of the cylindrical base 207. While only two bores 212 are shown, additional bores 212 for additional heaters can be similarly arranged. As explained with reference to FIGS. 7 and 8, the bores 212 are arranged so as to not interfere with the plurality of bores (shown in FIG. 7A) that supply process gases from the gas inlet 208 to the plenum 224. The bores 212 also do not interfere with the bore 214 for the temperature sensor (shown in FIG. 8).

FIG. 7A shows a cross-section of the showerhead 200 taken along lines C-C shown in FIG. 3. The cross-section C-C shows a plurality of bores 254-1, 254-2 (hereinafter the bores 254) that extend laterally outwards and downwards towards the base portion 202. The bores 254 extend through the conical portion 209 of the backplate 204 from the distal end 251 of the bore 250. The bores 254 descend from the distal end 251 of the bore 250 at an acute angle relative to the vertical axis of the showerhead 200. The bores 254 can be but need not be parallel to the walls of the conical portion 209 of the backplate 204. When the bores 254 are parallel to the walls of the conical portion 209, the angle between each of the bores 254 and the plane (or diameter) of the base portion 202 is α. The bores 254 extend down to the bottom surface 211 of the cylindrical base 207. When the base portion 202 with the plenum 224 is attached to the cylindrical base 207, the bores 254 connect to the plenum 224 in the base portion 202. The bores 254 connect to the plenum 224 near the ID of the rim 203 at 252-1 and 252-2. The bores 254 are in fluid communication with the plenum 224.

While only two bores 254 are shown, additional bores 254 can be similarly arranged. The bores 254 are arranged so as to not interfere with the bores 212 for the heaters (shown in FIG. 6). The bores 254 are arranged so as to not interfere with the bore 214 for the temperature sensor (shown in FIG. 8). The process gases from the gas delivery system 130 shown in FIG. 1A flow through the gas inlet 208, the bore 250, the bores 254, the plenum 224, and the through holes 222 into the processing chamber 102 shown in FIG. 1A.

FIG. 7B shows an alternate way to form the plenum 224. Instead of forming the pillars 220 in the base portion 202, the pillars 220 can be formed at the bottom surface 211 of the cylindrical base 207 of the backplate 204.

The pillars 220 can be formed in a bottom center region 534 of the cylindrical base 207 of the backplate 204. The bottom center region 534 of the cylindrical base 207 lies between an upper region 506 of the cylindrical base 207 and the bottom surface 211 of the cylindrical base 207. That is, the bottom center region 534 of the cylindrical base 207 lies between the upper region 506 of the cylindrical base 207 and the top surface 205 of the base portion 202. The bottom center region 534 is concentric with the cylindrical base 207. The bottom center region 534 has a smaller diameter than the cylindrical base 207. The bottom center region 534 has a smaller diameter than the ID of the rim 203 of the base portion 202. The bottom center region 534 lies between distal ends of the bores 254 that connect to the plenum 224 at 252-1 and 252-2.

The bottom center region 534 can be machined to form the pillars 220 in a recess 535. The recess 535 is cylindrical. The recess 535 is concentric with the cylindrical base 207. The recess 535 is has a smaller diameter than the bottom center region 534. The recess 535 is has a depth h1. The diameter of the slot 535 is less than or equal to the ID of the rim 203 of the base portion 202. The recess 535 extends radially in the bottom center region 534. The bores 254 connect to the recess 535 at the periphery or an OD of the recess 535 at 252-1, 252-2. Accordingly, when the base portion 202 is sealingly attached to the cylindrical base 207, the bores 254 are in fluid communication with the recess 535. The pillars 220 extend vertically downwards from the upper region 506 of the cylindrical base 207 through the recess 535. The pillars 220 extend towards the bottom surface 211 of the cylindrical base 207 parallel to the vertical axis of the showerhead 200. The pillars 220 contact the bottom surface 211 of the cylindrical base 207. The pillars 220 are distributed across the recess 535. A height h2 of the pillars 220 is equal to the depth h1 of the recess 535 to allow the process gases to flow in the plenum 224.

The plenum 224 is defined by the bottom center region 534, the recess 535, and the pillars 220. The pillars 220 are arranged across the recess 535 in the pattern described above with reference to FIGS. 4 and 5 (i.e., in the same manner as the pillars 220 can be alternatively arranged in the base portion 202 as described above). The pillars 220 provide solidity to the plenum 224 as described above. The through holes 222 are drilled from the bottom surface 213 of the base portion 202 into the recess 536. The pillars 220 are interstitial with the through holes 222. The process gases flow through the bores 254, the plenum 224, and exit the through holes 222 into the processing chamber 102 shown in FIG. 1A.

FIG. 8 shows a cross-section of the showerhead 200 taken along lines D-D shown in FIG. 3. The cross-section D-D shows the bore 214 for the temperature sensor. The bore 214 extends vertically downwards through the stem portion 206 into the conical portion 209 of the backplate 204. The bore 214 extends towards the base portion 202 along the vertical axis of the showerhead 200. The bore 214 extends into the conical portion 209 of the backplate 204 approximately up to the top of the cylindrical base 207 of the backplate 204. The bore 214 does not extend to the bottom surface 211 of the cylindrical base 207. While only one bore 214 is shown, additional bores 214 for additional temperature sensors can be similarly arranged. The bore (or bores) 214 is arranged so as to not interfere with the bores 212 for the heaters (shown in FIG. 6). The bore (or bores) 214 is arranged so as to not interfere with the bores 254 for the process gases (shown in FIG. 7A).

### Second Showerhead (Single Plenum, Monolithic)

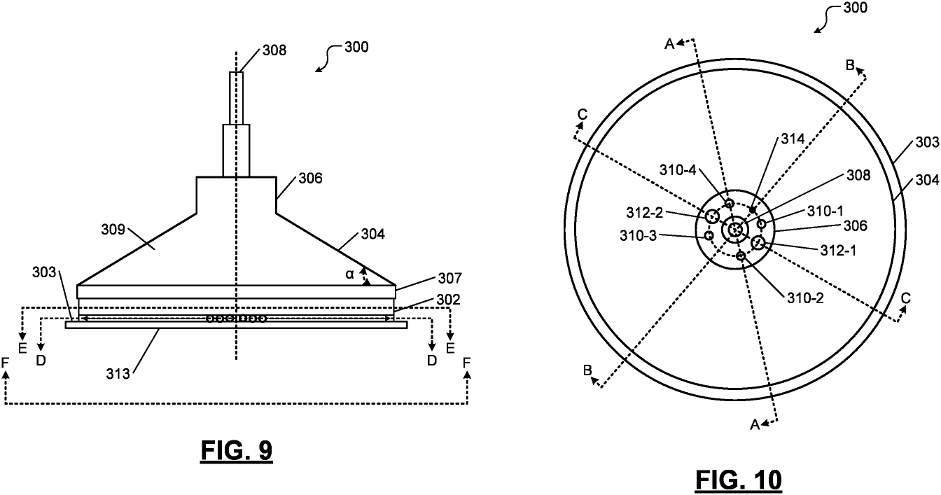

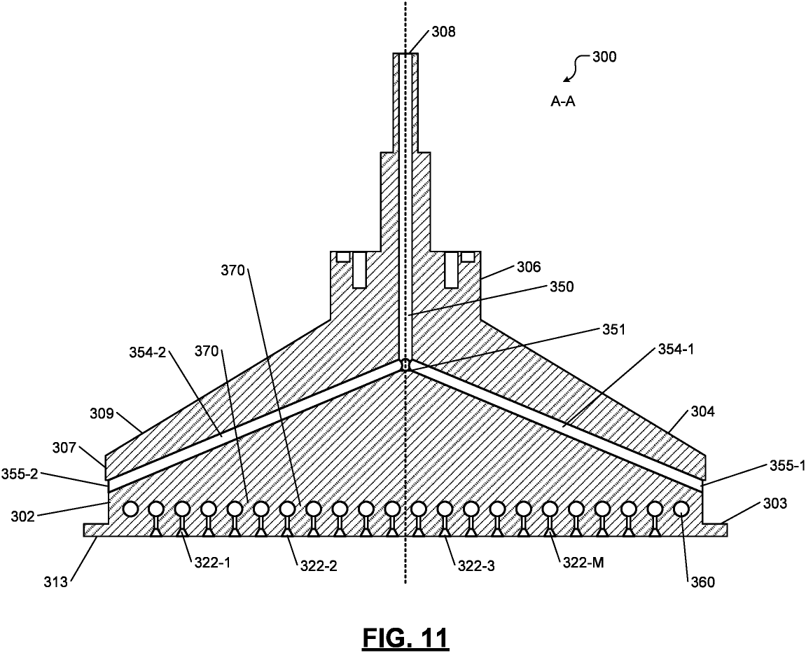

FIGS. 9-21 show various views of a second showerhead 300. FIG. 9 shows a side view of the showerhead 300. FIG. 10 shows a top view of the showerhead 300. FIGS. 11-21 show various cross-sectional views of the showerhead 300. Each cross-sectional view shows different features of the showerhead 300.

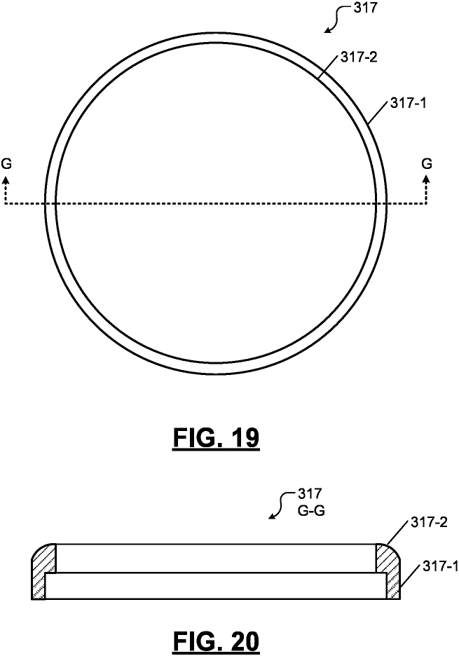

Unlike the showerhead 200, the showerhead 300 is monolithic (i.e., made of a single piece of metal). Specifically, the base portion 202 and the backplate 204 of the showerhead 200 are two separate pieces. In contrast, the base portion and the backplate of the showerhead 300 are made from a single metal piece. Therefore, the showerhead 300 is described as comprising various portions or elements for the purpose of describing the features of the showerhead 300. However, these portions or elements are not separate or distinct from each other and are not joined or attached to each other (except for a ring shown as element 317 in FIGS. 19-21). Rather, these portions or elements are made from a single piece of metal.

In FIG. 9, the showerhead 300 comprises a base portion 302, a backplate 304, and a stem portion 306. The base portion 302 is cylindrical. The bottom of the base portion 302 faces the substrate 106 shown in FIG. 1A. The bottom of the base portion 302 comprises a flange 303 that extends radially outwards. The ring 317 shown in FIGS. 19-21 is sealingly attached to the flange 303 and to the backplate 304 as shown and described with reference to FIGS. 19-21. The base portion 302 is described in further detail with reference to FIGS. 14-18.

The backplate 304 comprises a cylindrical base 307 and a conical portion 309. The cylindrical base 307 extends vertically upwards from the base portion 302. An outer diameter (OD) of the cylindrical base 307 is greater than an OD of the base portion 302. The OD of the cylindrical base 307 is less than an OD of the flange 303. The conical portion 309 extends vertically upwards from the cylindrical base 307 to the stem portion 306. Since the showerhead 300 is monolithic, the cylindrical base 307 and the conical portion 309 of the backplate 304 are also monolithic. Further, the base portion 302, the backplate 304, and the stem portion 306 are monolithic.

The backplate 304 is solid (i.e., is not hollow). The backplate 304 helps conduct heat from the base portion 302 to the heat sink 113 shown in FIG. 1A. The conical portion 309 slants relative to the cylindrical base 307 at an angle α. The angle α determines (in direct proportion) the volume of the conical portion 309. The angle α determines the heat conduction through the backplate 304. The angle α determines the weight of the showerhead 300. Greater volume of the conical portion 309 is desirable to conduct more heat. However, the angle α is selected so as to balance the heat conduction through the backplate 304 and the weight of the showerhead 300. For example, the angle α is about 45° but can be between 10° and 60°. The backplate 304 is described in further detail with reference to FIGS. 11-13.

A gas inlet 308 is provided in the center of the stem portion 306 to receive process gases from the gas delivery system 130 shown in FIG. 1A. The internal structure of the showerhead 300 including a plenum and various bores for heaters, gas supply, and temperature sensors is shown and described in detail with reference to FIGS. 11-21.

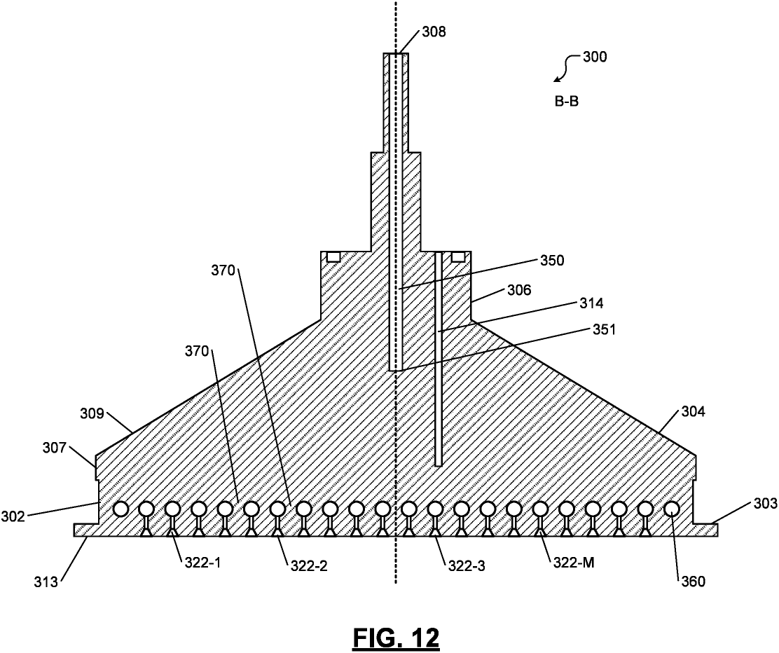

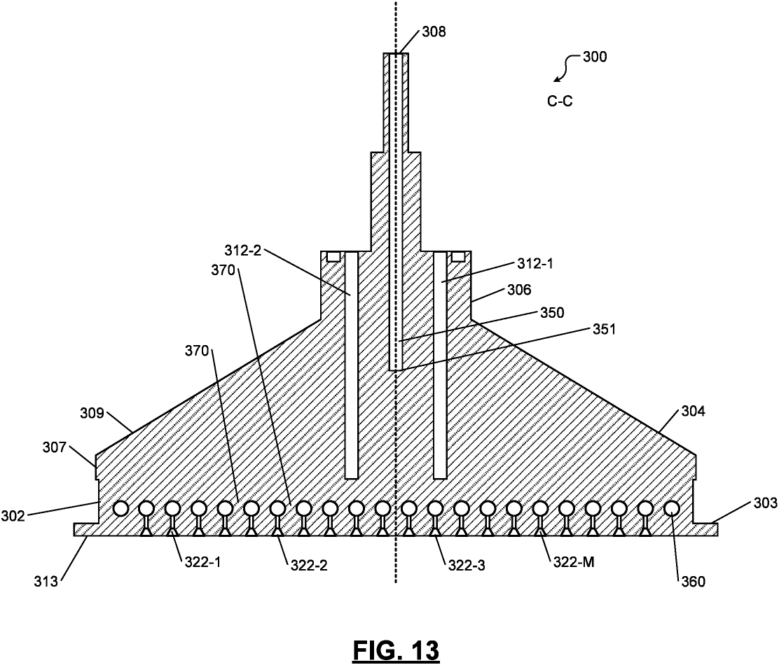

FIG. 10 shows a top view of the showerhead 300. The stem portion 306 comprises bores 310-1, 310-2, 310-3, and 310-4 (collectively, the bores 310). The bores 310 receive fasteners (not shown) used to attach the showerhead 300 to the top plate of the processing chamber 102 shown in FIG. 1A. The stem portion 306 comprises bores 312-1 and 312-2 (collectively, the bores 312). The stem portion 306 comprises a bore 314 through which a temperature sensor (e.g., a thermocouple) is disposed into the backplate 304 as shown in FIG. 12. Heaters are disposed through the bores 312 as shown in FIG. 13.

Various cross-sections of the showerhead 300 are identified in FIGS. 9 and 10. These cross-sections are shown in FIGS. 11-21 and are used to describe the internal structure of the showerhead 300 including the plenum and the bores for heaters, gas supply, and temperature sensors in further detail.

FIG. 11 shows a cross-section of the showerhead 300 taken along lines A-A shown in FIG. 10. The cross-section A-A shows a bore 350 that extends from the gas inlet 308 vertically downwards towards the base portion 302 through the stem portion 306. The bore 350 extends into the conical portion 309 of the backplate 304 along a vertical axis of the showerhead 300. The vertical axis of the showerhead 300 is similar to that of the showerhead 200 shown in FIGS. 1-8 and is therefore not redefined for brevity. The bore 350 extends through the center of the stem portion 306 and through the center of the conical portion 309 of the backplate 304. A distal end 351 of the bore 350 extends approximately half-way through the conical portion 309 of the backplate 304 as shown. Alternatively, the distal end 351 of the bore 350 can extend further up or down in the conical portion 309 of the backplate 304.

The cross-section A-A shows a plurality of bores 354-1, 354-2 (hereinafter the bores 354) that extend laterally outwards and downwards towards the base portion 302. The bores 354 extend through the conical portion 309 and the cylindrical base 307 of the backplate 304 from the distal end 351 of the bore 350. The bores 354 open where a bottom end of the cylindrical base 307 and a top end of the base portion 302 meet. Specifically, the bores 354 have openings 355-1, 355-2 (collectively the openings 355) at the bottom end of the cylindrical base 307 and at the top end of the base portion 302. The openings 355 of the bores 354 are flush (i.e., level) with the OD of the base portion 302.

The bores 354 descend from the distal end 351 of the bore 350 at an acute angle relative to the vertical axis of the showerhead 300. The bores 354 can be but need not be parallel to the walls of the conical portion 309 of the backplate 304. When the bores 354 are parallel to the walls of the conical portion 309, the angle between each of the bores 354 and the base portion 302 is α. While only two bores 354 are shown, additional bores 354 can be similarly arranged. The bores 354 are arranged so as to not interfere with the bore 314 for the temperature sensor (shown in FIG. 12). The bores 354 are arranged so as to not interfere with the bores 312 for the heaters (shown in FIG. 13).

The base portion 302 comprises a plenum 360 defined by a plurality of bores (shown in FIGS. 14A and 14B) drilled horizontally through the base portion 302. The plenum 360 and the bores are shown and described in detail with reference to FIGS. 14 and 15. Briefly, at least two sets of bores are cross-drilled through the base portion 302 forming vertical pillars at the intersections of the cross-drilled bores. A plurality of through holes (also called orifices) 322-1, 322-2, 322-3, ..., and 322-M (collectively, through holes 322), where M is a positive integer, are drilled around the pillars from a bottom surface 313 of the base portion 302. The through holes 322 extend from the bottom surface 313 of the base portion 302 into the plenum 360 defined by the cross-drilled bores. The through holes 322 and the plenum 360 are shown in further detail in FIGS. 14-18.

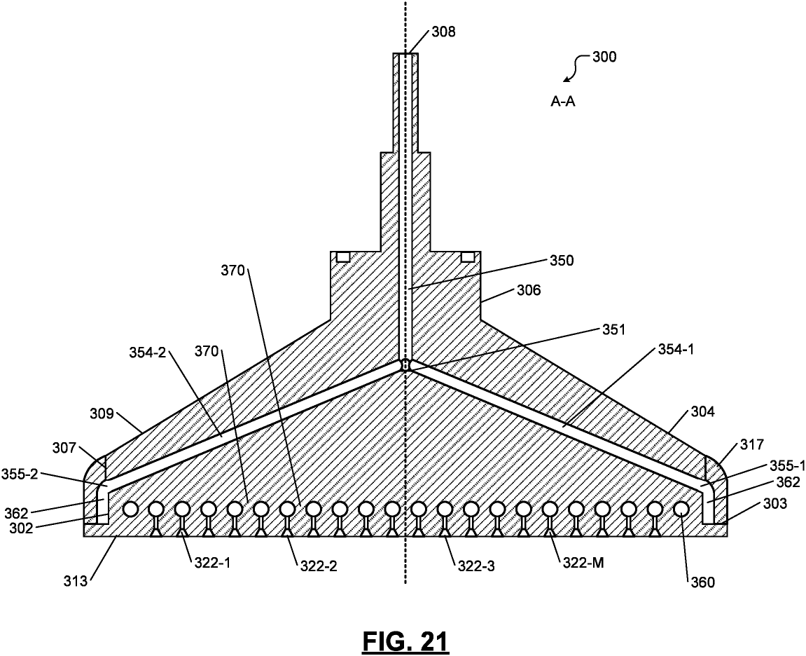

The process gases from the gas delivery system 130 shown in FIG. 1A flow through the gas inlet 308, the bore 350, and the bores 354. The ring (element 317 shown in FIGS. 19-21) is sealingly attached to the flange 303 of the base portion 302 and to the OD of the cylindrical base 307 of the backplate 304 defining an annular plenum 362 (shown in FIG. 21). The annular plenum 362 is defined between the ring 317, the OD of the cylindrical base 307 of the backplate 304, and the OD of the base portion 302. The annular plenum 362 is in fluid communication with the plenum 360 defined by the cross-drilled bores as shown and described in detail with reference to FIGS. 20-21. Accordingly, the annular plenum 362 and the plenum 360 form a single plenum enclosed by the ring 317 and are hereinafter collectively called the plenum 360. The plenum 360 is in fluid communication with the through holes 322. The process gases flow through the openings 355 of the bores 354 at the OD the base portion 302 and through the plenum 360 in the base portion 302 (shown in detail in FIGS. 14 and 15). The process gases exit via the through holes 322 into the processing chamber 102 shown in FIG. 1A.

FIG. 12 shows a cross-section of the showerhead 300 taken along lines B-B shown in FIG. 10. The cross-section B-B shows the bore 314 for the temperature senor. The bore 314 extends vertically downwards through the stem portion 306 into the conical portion 309 of the backplate 304. The bore 314 extends towards the base portion 302 along the vertical axis of the showerhead 300. The bore 314 extends into the cylindrical base 307 of the backplate 304. The bore 314 does not extend to the base portion 302. While only one bore 314 is shown, additional bores 314 for additional temperature sensors can be similarly arranged. The bore (or bores) 314 is arranged so as to not interfere with the bores 354 for the process gases (shown in FIG. 11). The bore (or bores) 314 is arranged so as to not interfere with the bores 312 for the heaters (shown in FIG. 13).

FIG. 13 shows a cross-section of the showerhead 300 taken along lines C-C shown in FIG. 10. The cross-section C-C shows the bores 312 for the heaters in detail. The bores 312 extend vertically downwards through the stem portion 306 towards the base portion 302 along the vertical axis of the showerhead 300. The bores 312 extend into the cylindrical base 307 of the backplate 304. While only two bores 312 are shown, additional bores 312 for additional heaters can be similarly arranged. The bores 312 are arranged so as to not interfere with the bores 354 for process gases (shown in FIG. 11). The bores 312 are arranged so as to not interfere with the bore 314 for the temperature sensor (shown in FIG. 12).

FIGS. 14A and 14B show a cross-section of the showerhead 300 taken along lines D-D shown in FIG. 9. In FIG. 14A, the cross-section D-D shows the cross-drilled bores and the plenum 360. Accordingly, the plenum 360 is called a cross-bored plenum 360. In the example shown, two sets of bores are cross-drilled through the base portion 302 orthogonally (i.e., perpendicular to each other). Specifically, a first set of bores 380-1, 380-2, 380-3, ..., 380-N (collectively, the first set of bores 380), where N is a positive integer, is drilled horizontally through the base portion 302. The first set of bores 380 is drilled along a first axis 382 (i.e., along chords of the base portion 302 parallel to the first axis 382). A second set of bores 390-1, 390-2, 390-3, ..., 390-N (collectively, the second set of bores 390), where N is a positive integer, is drilled horizontally through the base portion 302. The second set of bores 390 is drilled along a second axis 392 (i.e., along chords of the base portion 302 parallel to the second axis 392). The first axis 382 is perpendicular to the second axis 392.

The first and second sets of bores 380, 390 create pillars 370-1, 370-2, 370-3, ..., and 370-M (collectively, the pillars 370), where M is a positive integer greater than N, at the intersections of the first and second sets of bores 380, 390. Specifically, since the first and second sets of bores 380, 390 are drilled perpendicularly to each other, the pillars 370 are rectangular in shape. More specifically, in the example shown, the bores in the first and second sets of bores 380, 390 are of equal diameter and are equidistant from each other. Consequently, the pillars 370 are square in shape.

The pillars 370 are distributed from the center of the base portion 302 to the OD of the base portion 302. The pillars 370 help conduct heat from the bottom surface 313 of the base portion 302 to the cylindrical base 307 of the backplate 304. The backplate 304 conducts the heat to the heat sink 113 shown in FIG. 1A. The pillars 370 conduct the heat along the vertical axis of the showerhead 300. The heat conduction reduces radial temperature gradients across the base portion 302 and the backplate 304.

The first and second sets of bores 380, 390 define the plenum 360 within the base portion 302. The pillars 370 reduce the volume (i.e., cavity or hollowness) of the plenum 360. In other words, the pillars 370 provide solidity to the plenum 360. For example, the pillars 370 fill about 10% of the volume of the plenum 360. The amount of heat conducted by the pillars 370 from the bottom surface 313 of the base portion 302 to the cylindrical base 307 of the backplate 304 is directly proportional to a density of the pillars 370. The density of the pillars 370 is the number of pillars 370 per unit area of the base portion 302 in the plenum 360. In other words, the amount of heat conducted by the pillars 370 is directly proportional to the number of pillars 370. The density of the pillars 370 is specified by requirements of processes performed on the substrate 106.

The through holes 322 are distributed radially from the center of the base portion 302 to the OD of the base portion 302. Specifically, the through holes 322 are drilled around each pillar 370 as shown. Some of the through holes 322 are not visible in FIG. 14A and are shown in detail in FIG. 14B. In the example shown, as shown in FIG. 14B, when the bores in the first and second sets of bores 380, 390 are of equal diameter and are equidistant from each other, four pillars 370 lie on vertices of a square 371. The four pillars 370 include two pillars 370 along the first axis 382 and two pillars 370 along the second axis 392. One pillar 370 lies at the center of the square 371 (i.e., at the intersection of the diagonals of the square 371). One through hole 322 lies between each successive pillar 370 along the first and second axes 382, 392. Thus, two through holes 370 lie on each diagonal of the square 371. Additionally, one through hole 322 lies at the center of each side of the square 371. Accordingly, each pillar 370 is surrounded by eight through holes 322. The eight through holes 322 are arranged as follows.

Of the eight through holes 322, a first set of four through holes 322 lie on vertices of a square 396. The vertices of the square 396 lie at the centers of the four sides of the square 371. A second set four through holes 322 lie at the centers of the four sides of the square 396. The pillar 370 that lies at the center of the square 371 also lies at the center of the square 396. The second set of four through holes 322 that lie at the centers of the four sides of the square 396 lie on the diagonals of the square 371.

In some examples, the spacing between the bores in the first set of bores 380 may be different than the spacing in the second set of bores 390. For example, the bores in the first set of bores 380 may be separated from each other by a first distance. The bores in the second set of bores 390 may be separated from each other by a second distance. In other examples, the bores in the first set of bores 380 and/or in the second set of bores 390 may be spaced (i.e., separated from each other) by gradually varying distances. For example, the distance between the bores in the first set of bores 380 and/or in the second set of bores 390 may increase from the center of the base portion 302 towards the circumference of the base portion 302. In some examples, the distance between the bores in the first set of bores 380 and/or in the second set of bores 390 may decrease from the center of the base portion 302 towards the circumference of the base portion 302.

In still other examples, the number of bores in the first set of bores 380 and the second set of bores 390 may be equal. In further examples, some of the bores in the first set of bores 380 and/or in the second set of bores 390 may be omitted. In some examples, the diameters of the bores in the first set of bores 380 and/or in the second set of bores 390 may be varied similar to the spacing variations described above. In still other examples, the bores in the first set of bores 380 and/or in the second set of bores 390 may be arranged in groups. In these still other examples, the spacing (i.e., distance) between the bores and/or the diameters of the bores in the groups may be varied as described above.

Further, the two sets of bores 380, 390 are shown for example only. In some examples additional sets of bores can be drilled creating pillars of different shapes. The variations in quantity (i.e., the number of bores in a set) and/or diameter, the variations in spacing and grouping of the bores described above can be added to these additional sets of bores creating different patterns of pillars. The arrangement of the bores may be dictated by the pattern of the through holes 322 specified by the processes performed on the substrate 106.

FIG. 15 shows a cross-section of the showerhead 300 taken along lines E-E shown in FIG. 9. The cross-section E-E shows a section 315 of the base portion 302 that lies above the plenum 360. The section 315 is taken along a horizontal plane parallel to the diameter of the base portion 302 and perpendicular to the vertical axis of the showerhead 300. The first and second sets of bores 380, 390 and the plenum 360 lie under the section 315 of the base portion 302. The first and second sets of bores 380, 390 and the plenum 360 are parallel to the section 315 of the base portion 302. The cylindrical base 307 of the backplate 304 lies on top of the section 315 of the base portion 302. The cylindrical base 307 of the backplate 304 is parallel to the section 315 of the base portion 302.

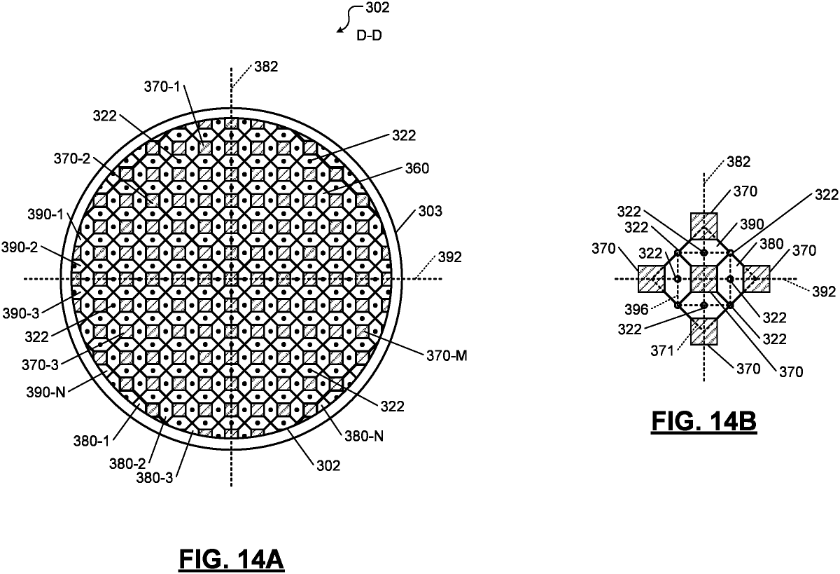

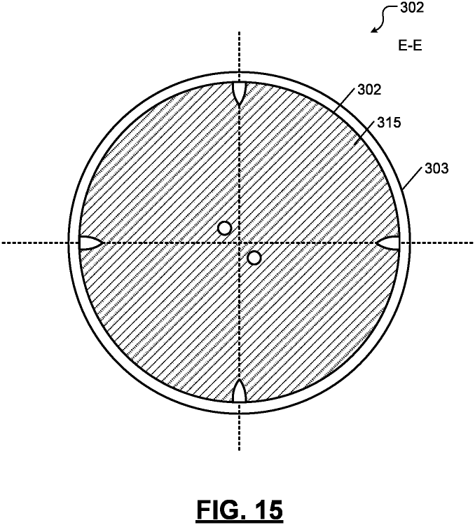

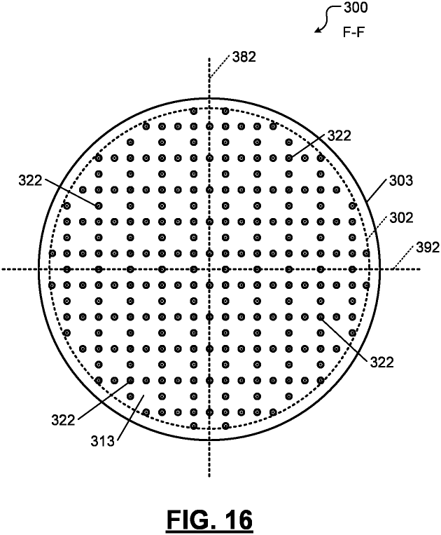

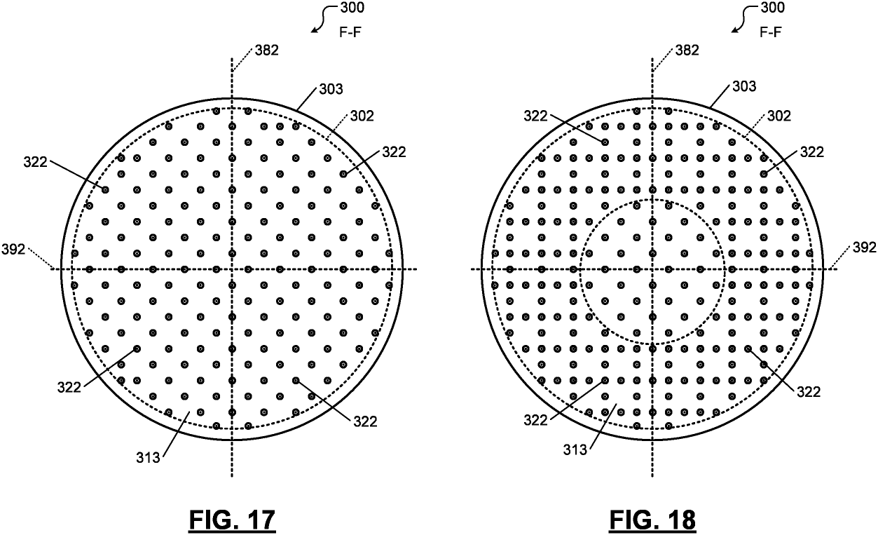

FIG. 16 shows a bottom view of the showerhead 300 taken along lines F-F shown in FIG. 9. The bottom view shows the through holes 322 arranged on the bottom surface 313 of the base portion 302. The through holes 322 are arranged on the bottom surface 313 of the base portion 302 in the pattern described above with reference to FIGS. 14A and 14B. Additional alternative patterns in which the through holes 322 can be arranged on the bottom surface 313 of the base portion 302 are shown in FIGS. 17 and 18.

In the example shown in FIG. 17, the through holes 322 are arranged on the bottom surface 313 of the base portion 302 in a square pattern or a diamond shaped pattern. In the example shown in FIG. 18, the through holes 322 are arranged using a combination of the patterns shown in FIGS. 16 and 17. The combination pattern is also called a zoned pattern. As shown, a first portion of the through holes 322 is arranged in the pattern shown in FIG. 17 in a center region (also called a first zone or an inner zone) of the base portion 302. The center region extends from the center of the base portion 302 to a predetermined portion of the radius of the base portion 302. A second portion of the through holes 322 is arranged in the pattern shown in FIG. 16 in a second region (also called a second zone or an outer zone) of the base portion 302. The second region extends from the periphery or an OD of the center region to the OD of the base portion 302. The center and second regions are concentric.

Alternatively, while not shown, the patterns shown in FIG. 18 can be reversed. That is, in the reversed pattern, the first portion of the through holes 322 is arranged in the pattern shown in FIG. 16 in the second region. Further, in the reversed pattern, the second portion of the through holes 322 is arranged in the pattern shown in FIG. 17 in center region. While only two concentric regions are shown, additional concentric regions may be used. Various patterns may be used to arrange the through holes 322 in the additional concentric regions. Further, while not shown, the through holes 322 may be arranged in pie shaped regions or zones. Furthermore, while not shown, the through holes 322 may be arranged in a combination of concentric and pie shaped regions or zones.

FIGS. 19-21 show the ring 317 (also called an annular sealing member) used to cover the openings 355 of the bores 354 described above. FIG. 19 shows a top view of the ring 317 that is sealingly attached to the cylindrical base 307 and the base portion 302 of the showerhead 300. The ring 317 has a bottom cylindrical portion 317-1 and an upper annular portion 317-2. The bottom cylindrical portion 317-1 has an outer diameter equal to the OD of the flange 303 of the base portion 302. The upper annular portion 317-2 initially extends vertically upwards from the bottom cylindrical portion 317-1. Then the upper annular portion 317-2 extends radially inwards towards the cylindrical base 307 of the backplate 304. An inner diameter of the upper annular portion 317-2 is equal to the OD of the cylindrical base 307 of the backplate 304. The ring 317 is monolithic. A distal end of the upper annular portion 317-2 is sealingly attached to cylindrical base 307 of the backplate 304. A distal end of the bottom cylindrical portion 317-1 is sealingly attached to the flange 303 of the base portion 302.

FIG. 20 shows a cross-section of the ring 317 taken along lines G-G shown in FIG. 19. FIG. 21 shows the cross-section A-A of the showerhead 300 shown in FIG. 11 with the addition of the ring 317. FIG. 21 shows the ring 317 that is sealingly attached to the flange 303 and to the periphery (OD) of the cylindrical base 307 of the backplate 304 as described above. The ring 317 prevents the process gases from the bores 354 from escaping (i.e., exiting) the showerhead 300. Instead, the ring 317 directs or routes the process gases from the bores 354 into the plenum 360. The base portion 302, the cylindrical base 307 of the backplate 304, the ring 317, the first and second sets of bores 380, 390 define the plenum 360 described above.

### Third Showerhead (Dual Plenum, Monolithic)

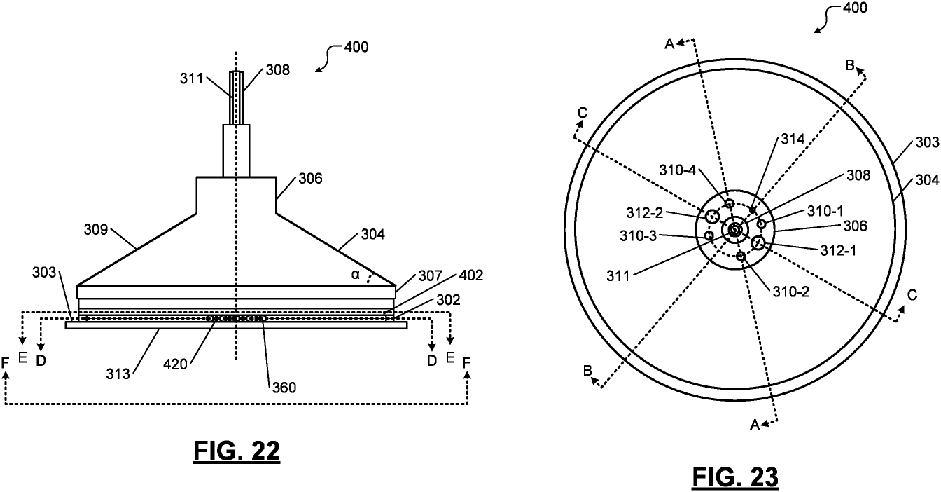

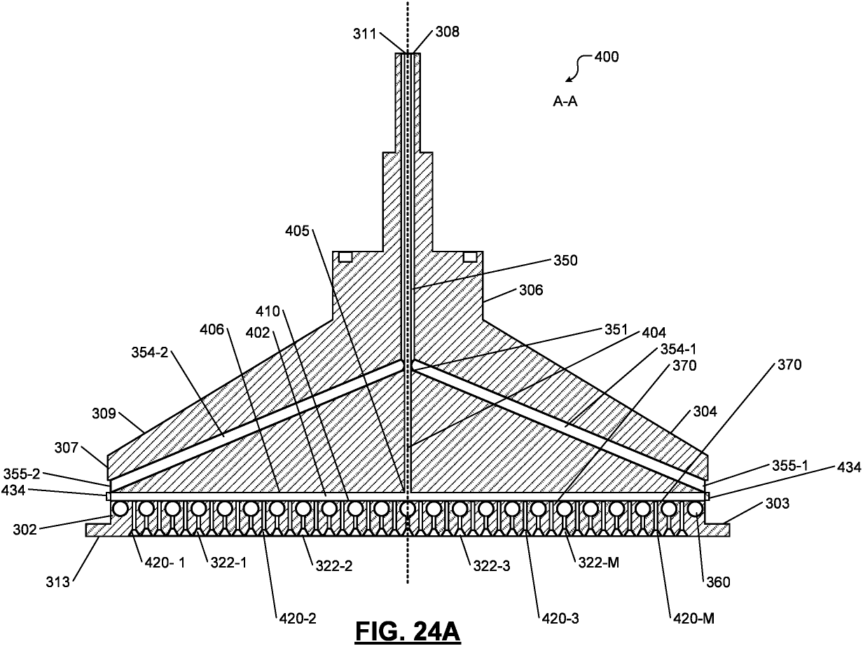

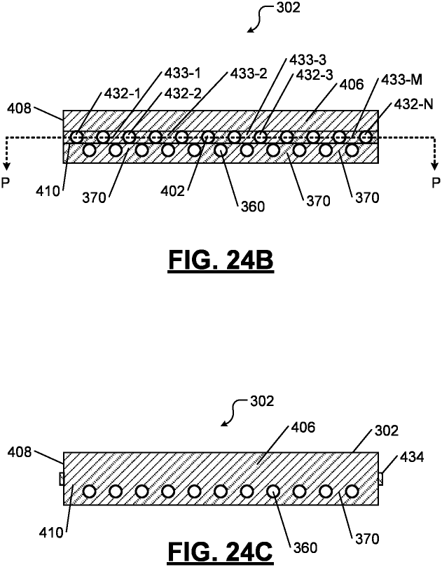

FIGS. 22-40 show various views of a third showerhead 400. FIG. 22 shows a side view of the showerhead 400. FIG. 23 shows a top view of the showerhead 400. FIG. 24A-40 show various cross-sectional views of the showerhead 400. Each cross-sectional view shows different features of the showerhead 400.

The showerhead 400 differs from the showerhead 300 in that unlike the showerhead 300, the showerhead 400 is a dual plenum showerhead. Accordingly, unlike the showerhead 300, the showerhead 400 allows supplying two different process gases into the processing chamber 102 as shown in FIG. 1B. Specifically, as shown in FIG. 24A-40 and as described below in further detail, the showerhead 400 defines two separate plenums. The two separate plenums are not in fluid communication with each other. The showerhead 400 comprises two separate gas inlets. The two separate gas inlets receive two separate process gases from the gas delivery system 130 shown in FIG. 1B. The two separate process gases are respectively supplied to the two separate plenums. Since the inlets and the plenums of the showerhead 400 are disjoint, the two separate process gases do not mix in the showerhead 400. While not shown, the design of the showerhead 400 can be extended to include additional disjoint inlets and plenums to supply additional process gases separately into the showerhead 400.

Additional differences between the showerhead 300 and the showerhead 400 are shown and described below with reference to FIGS. 22-40. Except for these differences, the showerhead 400 is similar to the showerhead 300. Therefore, identical reference numerals from the showerhead 300 are used to identify elements and features of the showerhead 400 that are similar to the respective elements and features of the showerhead 300, and their description is not repeated for brevity.

FIG. 22 shows that the showerhead 400 has the gas inlet 308 (hereinafter the first gas inlet 308) and a second gas inlet 311. The first and second gas inlets 308, 311 are coaxial. In addition to the plenum 360 (hereinafter the first plenum 360), the showerhead 400 further comprises a second plenum 402 in the base portion 302. The second plenum 402 extends radially across the base portion 302 as shown and described in detail with reference to FIG. 24A-26 and FIG. 40. Briefly, the second plenum 402 is located directly above the first plenum 360. The second plenum 402 is not in fluid communication with the first plenum 360. Instead, as shown and described with reference to FIGS. 24A-28C, top ends of the pillars 370 in the first plenum 360 abut the bottom of the second plenum 402. The top ends of the pillars 370 include through holes that extend from the bottom of the second plenum 402, through the pillars 370, and through the bottom surface 313 of the base portion 302. Accordingly, the through holes in the pillars 370 are in fluid communication with the second plenum 402 but are not in fluid communication with the first plenum 360.

A first gas supplied by the gas delivery system 130 shown in FIG. 1B flows through the first gas inlet 308. Specifically, the first gas flows through an annular volume between an outer wall of the second gas inlet 311 and an inner wall of the first gas inlet 308. A second gas supplied by the gas delivery system 130 shown in FIG. 1B flows through the second gas inlet 311. As shown and described in further detail with reference to FIGS. 24A-40, the first and second gases flow through bores extending from the first and second gas inlets 308, 311 into the first and second plenums 360, 402, respectively.

FIG. 23 is identical to FIG. 10 except that in addition to showing all elements shown in FIG. 10, FIG. 23 shows the additional second gas inlet 311 described above.

FIG. 24A shows a cross-section of the showerhead 400 taken along lines A-A shown in FIG. 23. FIG. 24A is identical to FIG. 11 except for the following additions. Hereinafter, the bore 350 is called the first bore 350. A second bore 404 extends from the second gas inlet 311 vertically downwards towards the base portion 302 through the stem portion 306. The second bore 404 extends into the conical portion 309 of the backplate 304 along a vertical axis of the showerhead 400. The vertical axis of the showerhead 400 is similar to that of the showerhead 300 and is therefore not redefined for brevity. The bore 404 extends through the center of the stem portion 306 and through the center of the backplate 304 into an upper region 406 of the base portion 302 of the showerhead 400. A distal end 405 of the bore 404 is connected to the second plenum 402 at the center of the second plenum 402. The second plenum 402 is shown and described below in further detail with reference to FIGS. 24B-24E.

FIGS. 24B and 24C show side views of the base portion 302 showing the second plenum 402 in further detail. In FIG. 24B, the second plenum 402 is formed in the upper region 406 of the base portion 302. The upper region 406 of the base portion 302 lies directly above an upper surface 410 of the first plenum 360. The second plenum 402 is formed by removing material from the upper region 406. The material is removed from the upper region 406 by cross-drilling bores through a plurality of openings 432-1, 432-2, 432-3, ..., and 432-N (collectively, the openings 432), where N is a positive integer. The openings 432 are formed on sidewalls 408 of the base portion 302. The bores are cross-drilled through the upper region 406 along the first and second axes 382, 392 (i.e., along chords of the base portion 302 parallel to the first and second axes 382, 392). The bores are cross-drilled through the upper region 406 similar to the manner in which the first and second sets of bores 380, 390 are drilled to form the first plenum 360.

The cross-drilled bores in the upper region 406 create a plurality of pillars 433-1, 433-2, 433-3, ..., and 433-M (collectively the pillars 433), where M is a positive integer. The cross-drilled bores in the upper region 406 create the pillars 433 in the upper region 406 (i.e., in the second plenum 402) directly above the upper surface 410 of the first plenum 360. The bores are cross-drilled through the upper region 406 parallel to and interstitially relative to the first and second sets of bores 380, 390 of the first plenum 360. The first and second sets of bores 380, 390 of the first plenum 360 are drilled directly below the second plenum 402 (i.e., directly below the upper surface 410 of the first plenum 360). The bores are cross-drilled through the upper region 406 such that the pillars 433 in the second plenum 402 are interstitial relative to the pillars 370 of the first plenum 360. The pillars 370 in the first plenum 360 are level (flush) with the upper surface 410 of the first plenum 360 and abut the bottom of the second plenum 402.

In FIG. 24C, a ring 434 (also called an annular sealing member) is sealingly attached to the upper region 406 of the base portion 302. The ring 434 covers the openings 432 on the sidewalls 408 of the base portion 302 to form the second plenum 402. In some examples, while not shown, plugs can be inserted into the openings 432 to close the openings 432 instead of attaching the ring 434 to the base portion 302 to form the second plenum 402. When the ring 434 is sealingly attached to the upper region 406 of the base portion 302 (or plugs are used to close the openings 432), the ring 434 (or the plugs) prevents process gases from the first and second plenums 360, 402 from mixing with each other.

Thus, the second plenum 402 is defined by the upper region 406 of the base portion 302, the upper surface 410 of the first plenum 360, the portions of the sidewalls 408 of the base portion 302 between the openings 432, and the ring 434 (or plugs) covering the openings 432 and the portions of the sidewalls 408 of the base portion 302. The second plenum 402 extends radially across the base portion 302 and lies in a plane perpendicular to the vertical axis of the showerhead 400.

In FIG. 24A, the second plenum 402 lies between the bores 354. Specifically, the second plenum 402 lies directly below a plane in which the openings 355 of the bores 354 lie. A plurality of through holes 420-1, 420-2, 420-3, ..., and 420-M (collectively the through holes 420), where M is a positive integer, are drilled at the bottom of the second plenum 402. The through holes 420 are drilled through the bottom surface 313 of the base portion 302 and through the center of the pillars 370 (one through hole 420 per pillar 370). The through holes 420 are in fluid communication with the second plenum 402 but are not in fluid communication with the first plenum 360. As shown and described in further detail with reference to FIGS. 24D, 24E, and 27A-28C, the through holes 420 of the second plenum 402 are arranged interstitially with the through holes 322 of the first plenum 360. The pillars 433 of the second plenum 402 are arranged interstitially with the pillars 370 of the first plenum 360.

The first gas flows through the first gas inlet 308, through the bores 350 and 354, the first plenum 360, and the through holes 322 into the processing chamber 102 shown in FIG. 1B. The second gas flows through the second gas inlet 311, through the bore 404, the second plenum 402, and the through holes 420 into the processing chamber 102 shown in FIG. 1B. The remaining features shown in FIG. 24A are shown and described with reference to FIG. 11, and their description is omitted for brevity.

FIGS. 24D and 24E show a cross-section of the second plenum 402 taken along lines P-P shown in FIG. 24B. The cross-section shows the layout of the pillars 433 and the through holes 420 in the second plenum 402. In FIG. 24D, the layout of the pillars 433 is similar to the layout of the pillars 370 shown in FIGS. 14A and 14B and is therefore not described again for brevity. The pillars 433 are structurally and functionally similar to the pillars 370. Therefore, all the structural and functional details of the pillars 370 described above with reference to the showerhead 300 apply equally to the pillars 433 and are therefore not repeated for brevity. The layout of the through holes 420 is described below with reference to FIG. 24E.

In FIG. 24E, the through holes 420 are arranged between each of the pillars 433. Specifically, when the bores drilled through the openings 432 are of equal diameter and are equidistant from each other, four pillars 433 lie on vertices of the square 371. The four pillars 433 include two pillars 433 along the first axis 382 and two pillars 433 along the second axis 392. One pillar 433 lies at the center of the square 371 (i.e., at the intersection of the diagonals of the square 371). One through hole 420 lies between each successive pillar 433 along the first and second axes 382, 392. Thus, two through holes 420 lie on each diagonal of the square 371. The four through holes 420 that lie on the diagonals of the square 371 also lie on vertices of the square 396. The vertices of the square 396 lie at the centers of the four sides of the square 371. Consequently, the pillar 370 that lies at the center of the square 371 also lies at the center of the square 396.

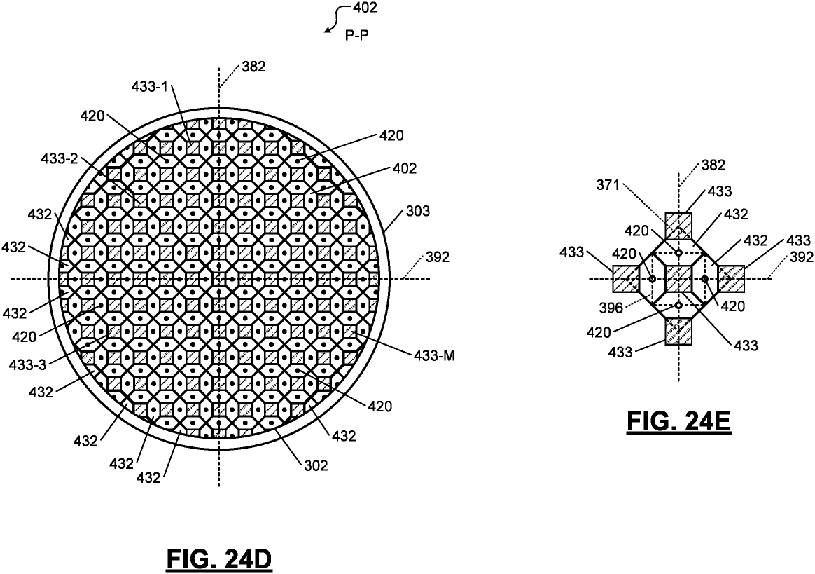

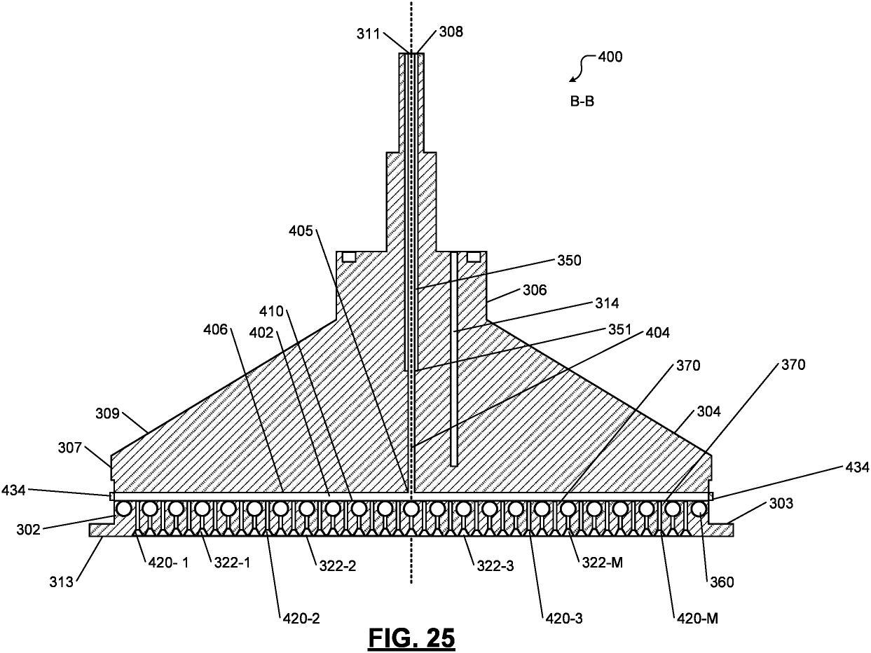

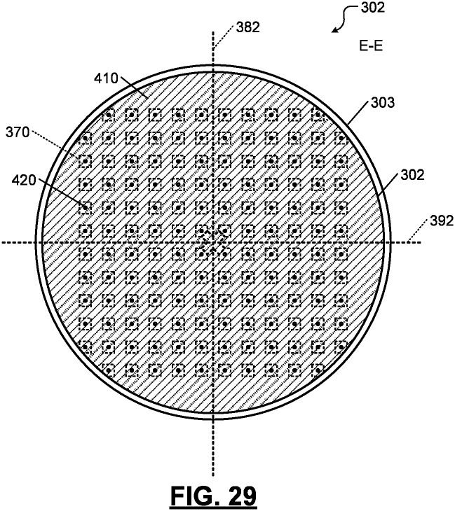

Accordingly, each pillar 433 is surrounded by four through holes 420 in a square pattern described above. The arrangement of the through holes 420 relative to the pillars 370 of the first plenum 360 is shown and described below with reference to FIG. 29. These features (e.g., the pillars 433, the bores, the openings 432, and the ring 434) of the second plenum 402 that are shown in FIGS. 24B-24E are omitted from FIGS. 25, 26, and 40 (but are presumed present therein). These features are omitted from FIGS. 25, 26, and 40 to simplify illustration of the other additional features of the showerhead 400 shown in these figures but are presumed present therein.

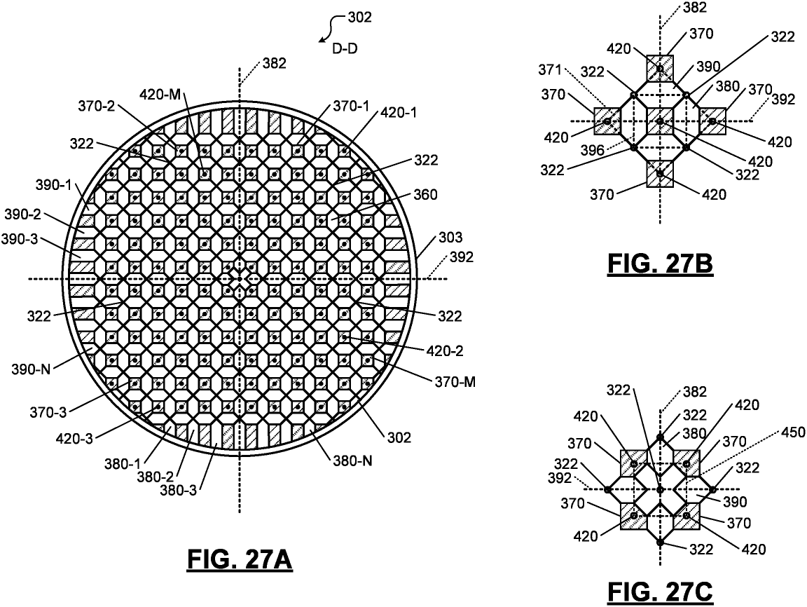

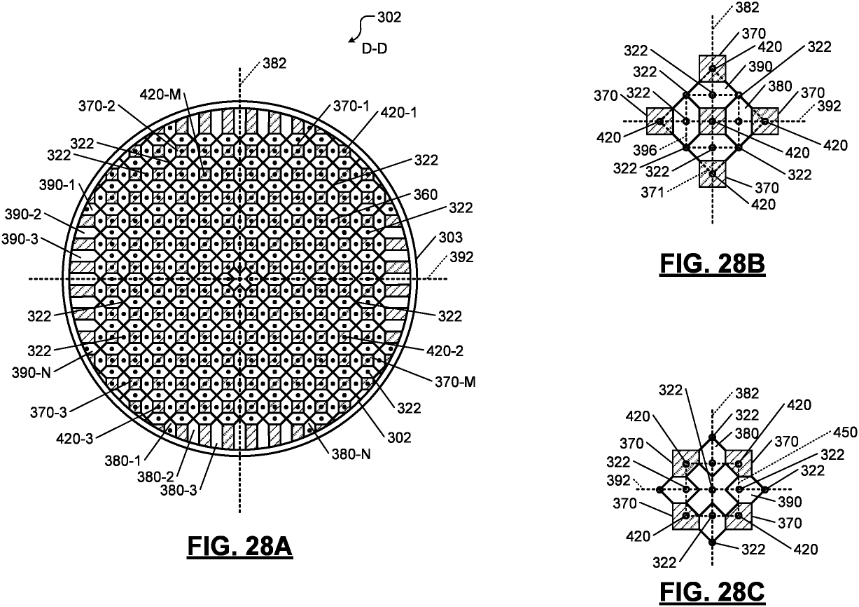

FIG. 25 shows a cross-section of the showerhead 400 taken along lines B-B shown in FIG. 23. FIG. 25 is identical to FIG. 12 except that in addition to showing all elements shown in FIG. 12, FIG. 25 shows the second gas inlet 311, the bore 404, the second plenum 402, the ring 434, and the through holes 420 described above. The arrangement of the pillars 370 and the through holes 322 shown in FIG. 25 is also different than the arrangement of the pillars 370 and the through holes 322 shown in FIG. 12. The different arrangement of the pillars 370 and the through holes 322 in FIG. 25 is shown and described in further detail with reference to FIGS. 27A-28C. The remaining features shown in FIG. 25 are shown and described with reference to FIG. 12 and their description is therefore omitted for brevity.

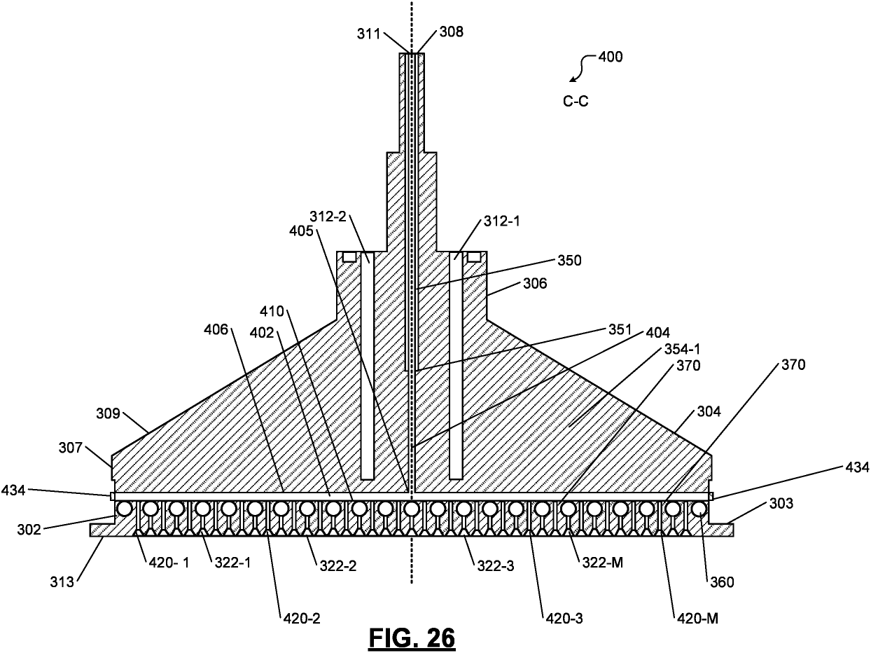

FIG. 26 shows a cross-section of the showerhead 400 taken along lines C-C shown in FIG. 23. FIG. 26 is identical to FIG. 13 except that in addition to showing all elements shown in FIG. 13, FIG. 26 shows the second gas inlet 311, the bore 404, the second plenum 402, the ring 434, and the through holes 420 described above. The arrangement of the pillars 370 and the through holes 322 shown in FIG. 26 is also different than the arrangement of the pillars 370 and the through holes 322 shown in FIG. 13. The different arrangement of the pillars 370 and the through holes 322 in FIG. 26 is shown and described in further detail with reference to FIGS. 27A-28C. The remaining features shown in FIG. 26 are shown and described with reference to FIG. 13 and their description is therefore omitted for brevity.

FIGS. 27A-28C show cross-sections of the base 302 302 taken along lines D-D shown in FIG. 22 showing the first plenum 360 in detail. FIGS. 27A-27C show a first pattern in which the pillars 370 and the through holes 322, 420 are arranged. FIGS. 28A-28C show a second pattern in which the pillars 370 and the through holes 322, 420 are arranged. The second pattern differs from the first pattern in that the second pattern comprises additional through holes 322 than the first pattern as explained below in detail. Some of the through holes 322 not visible in FIGS. 27A and 27B are shown in detail in FIGS. 27B, 27C, 28B, and 28C.

The first and second patterns differ from the pattern shown in FIGS. 14A and 14B as follows. In FIGS. 14A and 14B, the first and second sets of bores 380, 390 are drilled such that the center of the base portion 302 has a pillar 370. In contrast, in FIGS. 27A-28C, the first and second sets of bores 380, 390 are drilled such that the center of the base portion 302 has a through hole 322 instead of a pillar 370. In FIGS. 14A and 14B, the bores in the first and second sets of bores 380, 390 do not intersect at the center of the base portion 302. In contrast, in FIGS. 27A-28C, the bores in the first and second sets of bores 380, 390 intersect at the center of the base portion 302.

In addition, in FIGS. 14A and 14B, the pillars 370 do not include the through holes 420 since the showerhead 300 does not include the second plenum 402. In contrast, since the showerhead 400 comprises the second plenum 402, the pillars 370 in the first and second patterns shown in FIGS. 27A-28C include the through holes 420 as shown in FIGS. 27A-28C. In FIGS. 27B and 28B, when the bores in the first and second sets of bores 380, 390 are of equal diameter and are equidistant from each other, the through holes 420 lie at the vertices and the center of the square 371.

In FIGS. 27A and 27B, in the remaining portions of the first and second sets of bores 380, 390 (i.e., in the region of the base portion 302 that is radially outward from the center of the base portion 302), the first pattern of the pillars 370 and the through holes 322 is identical to that shown in FIGS. 14A and 14B except for the additional through holes 420, which are absent in FIGS. 14A and 14B, and two other differences. First, the first pattern shown in FIGS. 27A and 27B comprises the additional through holes 420 that are absent in the pattern shown in FIGS. 14A and 14B. Second, the first pattern shown in FIGS. 27A and 27B does not include the through holes 322 that lie at the centers of the four sides of the square 396 shown in FIGS. 14B and 28B.

In FIGS. 28A and 28B, in the remaining portions of the first and second sets of bores 380, 390 (i.e., in the region of the base portion 302 that is radially outward from the center of the base portion 302), the second pattern of the pillars 370 and the through holes 322 is identical to that shown in FIGS. 14A and 14B except for the additional through holes 420, which are absent in FIGS. 14A and 14B.

In the first and second patterns, as shown in FIGS. 27A, 27C, 28A, and 28C, the center of the base portion 302 has a through hole 322. When the bores in the first and second sets of bores 380, 390 are of equal diameter and are equidistant from each other, the centers of the pillars 370 immediately adjacent to the through hole 322 at the center of the base portion 302 lie on vertices of a square 450. Consequently, the through holes 420 in the pillars 370, which are at the center of the respective pillars 370, lie at the vertices of the square 450. The through hole 322 at the center of the base portion 302 lies at the center of the square 450. That is, the through hole 322 at the center of the base portion 302 lies at the intersection of the diagonals of the square 450. The side of the squares 450 and 371 are equal.

In FIG. 27A, subsequent to the pattern shown in FIG. 27C, in the region of the base portion 302 that is radially outward from the center of the base portion 302, the pattern of the pillars 370, the through holes 420, and the through holes 322 shown in FIG. 27B, extends (i.e., replicates) along the first and second axes 382, 392.

In FIG. 28C, in the second pattern, as shown in FIGS. 28A and 28C, the pattern of the pillars 370, the through holes 420, and the through holes 322 is identical to the pattern shown in FIG. 27C except that four additional through holes 322 lie at the centers of the four sides of the square 450.

The pattern shown in FIG. 28B is identical to the pattern shown in FIG. 14B except for the addition of the through holes 420 at the centers of the pillars 370 as shown in FIG. 28B. In FIG. 28A, subsequent to the pattern shown in FIG. 28C, in the region of the base portion 302 that is radially outward from the center of the base portion 302, the pattern of the pillars 370, the through holes 420, and the through holes 322 shown in FIG. 28B, extends (i.e., replicates) along the first and second axes 382, 392.

In FIGS. 27A-28C, the variations described with reference to FIGS. 14A and 14B regarding the arrangements and geometries of the first and second sets of bores 380, 390 can be employed while maintaining the patterns shown in FIGS. 27C and 28C at the center of the base portion 302. The variations are not described again for brevity. Further, corresponding variations can also be employed in drilling the bores used to form the second plenum 402.

FIGS. 29-37 show cross-sections of the base portion 302 taken along lines E-E shown in FIG. 22. The pillars 433 are omitted (but are presumed present) to simplify the illustrations of the through holes 322 and their alignment with the pillars 370. Each of the FIGS. 29-37 shows a different pattern of the through holes 420 that can be used in the showerhead 400 depending on different process requirements. Each of the FIGS. 29-37 shows a top view of the second plenum 402 and the through holes 420 that are at the center of the pillars 370. The pillars 370 are not visible but are shown in dotted lines to illustrate the alignment of the through holes 420 with the center of the pillars 370.

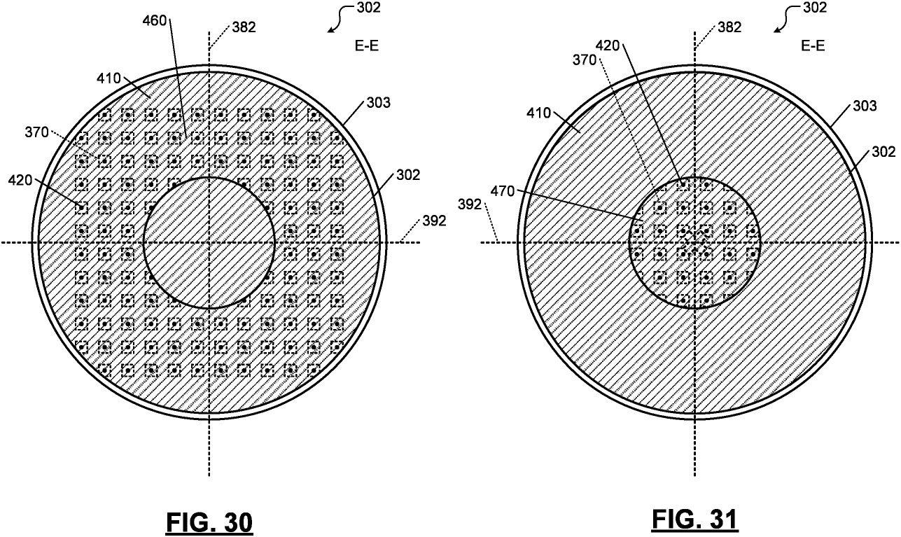

For example, FIG. 29 shows the pillars 370 and the through holes 420 arranged in the base portion 302 as shown in FIGS. 27A and 28A. In some examples, the through holes 420 can be arranged in zones (i.e., one or more regions of the base portion 302) instead of being arranged throughout the base portion 302 as shown in FIGS. 27A and 28A. For example, the zones can be radial, azimuthal, or a combination thereof. Various examples of zoned arrangements of the through holes 420 are shown in FIGS. 30-37.

For example, FIG. 30 shows the through holes 420 arranged in an outer radial zone 460 in the base portion 302. The outer radial zone 460 extends from a predetermined distance from the center of the base portion 302 to the OD of the base portion 302. FIG. 31 shows the through holes 420 arranged in an inner radial zone 470 in the base portion 302. The inner radial zone 470 extends from the center of the base portion 302 to a predetermined distance from the center of the base portion 302.

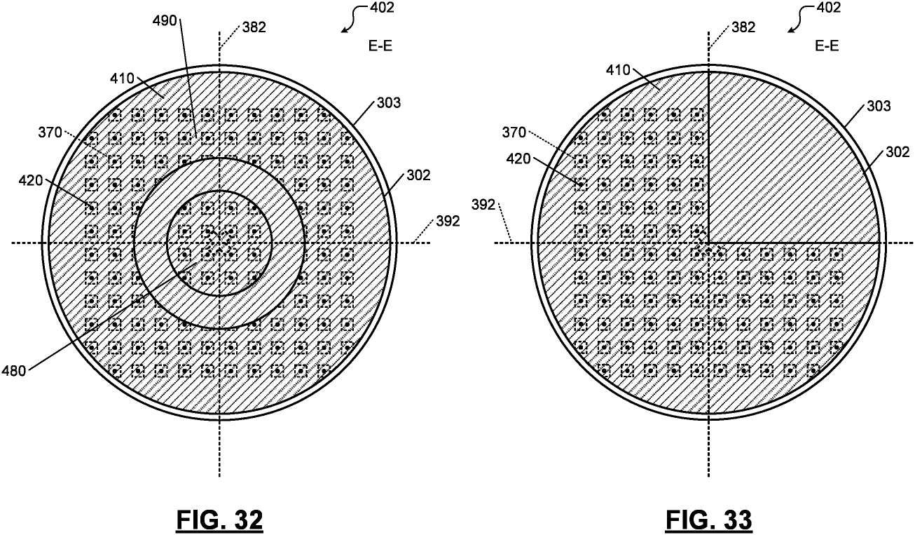

In other examples, FIG. 32 shows the through holes 420 arranged in concentric radial zones 480 and 490 in the base portion 302. The radial zone 480 is an inner radial zone, and the radial zone 490 is an outer radial zone arranged concentrically with the radial zone 480. The radial zone extends from the center of the base portion 302 to a first predetermined distance from the center of the base portion 302. The radial zone 490 extends from a second predetermined distance from the center of the base portion 302 to the OD of the base portion 302. The second predetermined distance is greater than the first predetermined distance.

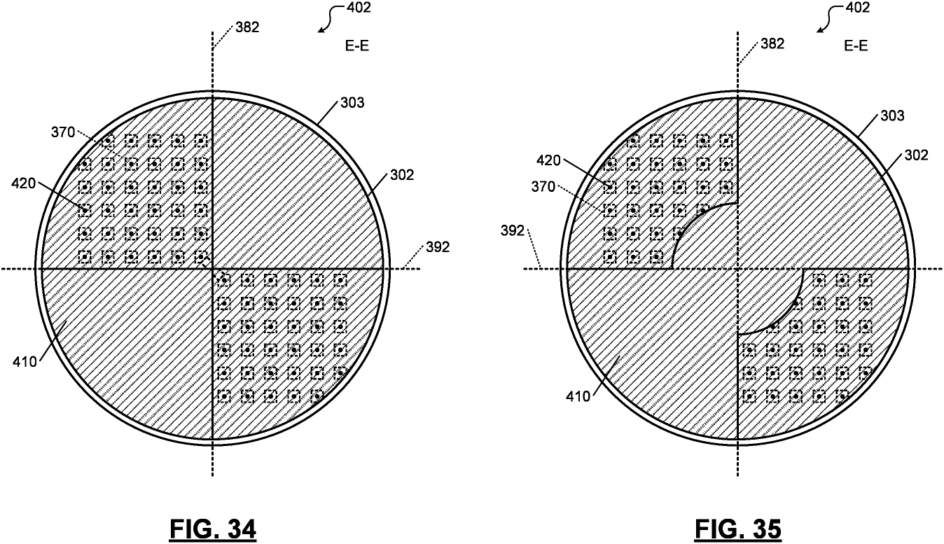

In further examples, FIGS. 33 and 34 show the through holes 420 arranged in azimuthal zones. For example, FIG. 33 shows the through holes 420 arranged in second, third, and fourth quadrants (as in co-ordinate geometry) of the base portion 302. Alternatively, while not shown, the through holes 420 can be arranged in any one of the four quadrants of the base portion 302. In another example, FIG. 34 shows the through holes 420 arranged in second and fourth quadrants of the base portion 302. Alternatively, while not shown, the through holes 420 can be arranged in first and second quadrants, first and fourth quadrants, second and third quadrants, or third and fourth quadrants of the base portion 302. In still other examples, FIGS. 35-37 show examples of the through holes 420 arranged in various combinations of radial and azimuthal zones in the base portion 302. Various other arrangements based on requirements of processing the substrate 106 are contemplated.

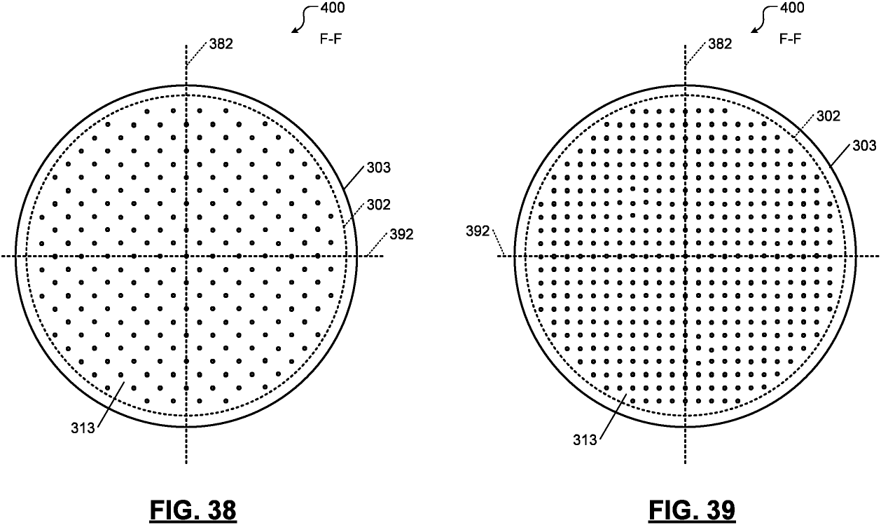

FIG. 38 shows a bottom view of the showerhead 400 taken along lines F-F shown in FIG. 22 and shows the through holes 322, 420 arranged on the bottom surface 313 of the base portion 302. The through holes 322, 420 are arranged in the pattern described above with reference to FIGS. 27A-27C.

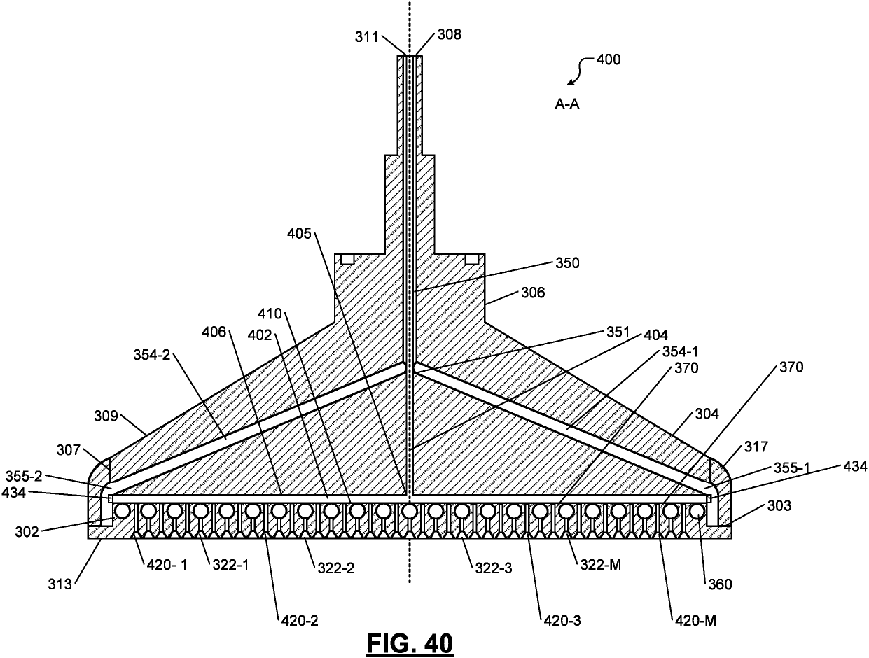

FIG. 39 shows an example of an alternative pattern in which the through holes 322, 420 can be arranged on the bottom surface 313 of the base portion 302. In this example, the through holes 322, 420 are arranged in the pattern described above with reference to FIGS. 28A-28C.

FIG. 40 is identical to FIG. 21 except that in addition to showing all elements shown in FIG. 21, FIG. 40 shows the second gas inlet 311, the bore 404, the second plenum 402, the ring 434, and the through holes 420 described above.

### Fourth Showerhead (Dual Plenum, Non-Monolithic)

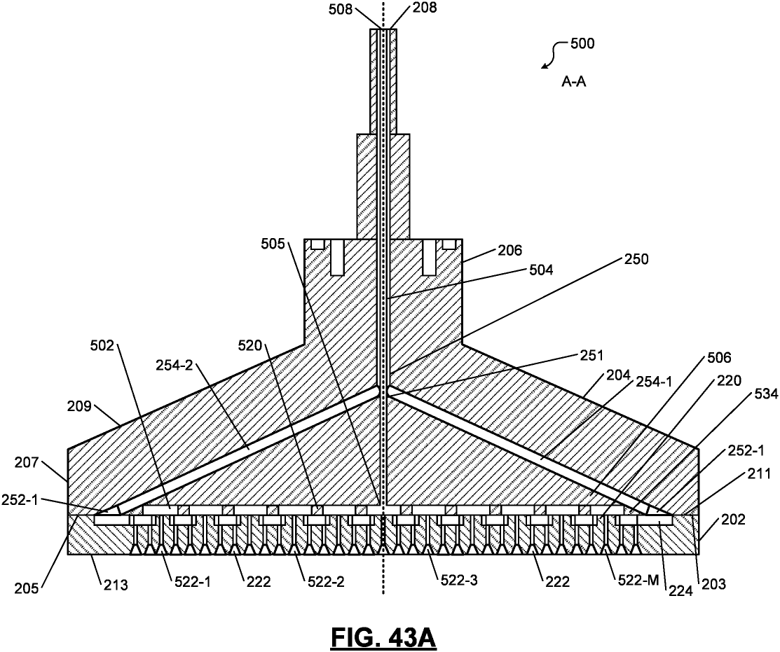

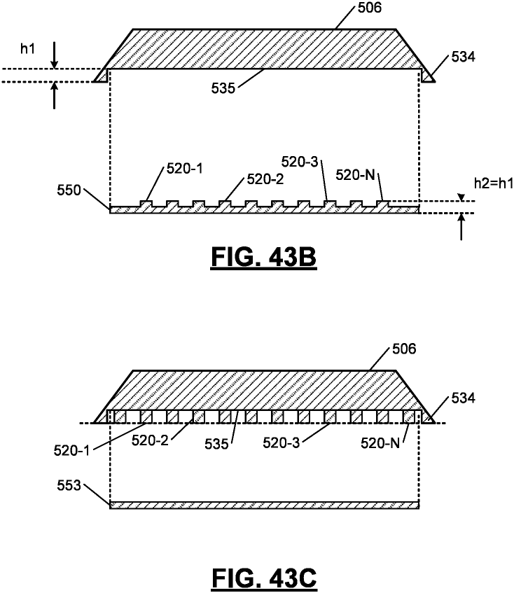

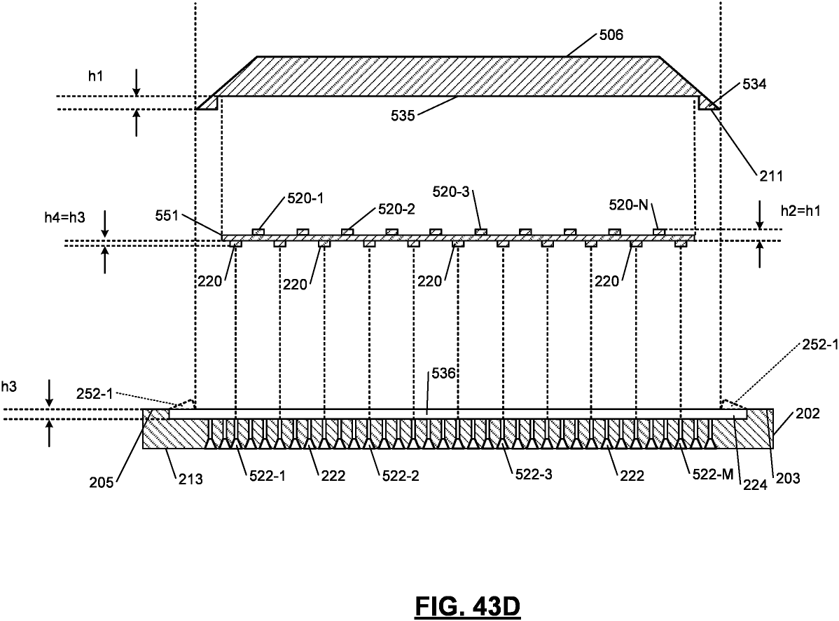

FIGS. 41-49 show various views of a fourth showerhead 500. FIG. 41 shows a side view of the showerhead 500. FIG. 42 shows a top view of the showerhead 500. FIGS. 43-49 show various cross-sectional views of the showerhead 500. Each cross-sectional view shows different features of the showerhead 500.

The showerhead 500 differs from the showerhead 200 in that unlike the showerhead 200, the showerhead 500 is a dual plenum showerhead. Accordingly, unlike the showerhead 200, the showerhead 500 allows supplying two different process gases into the processing chamber 102 as shown in FIG. 1B. Specifically, as shown in FIGS. 41-49 and as described below in further detail, the showerhead 500 defines two separate plenums that are disjoint and are not in fluid communication with each other. The showerhead 500 comprises two separate gas inlets that receive two separate process gases from the gas delivery system 130 shown in FIG. 1B. The two separate process gases are respectively supplied to the two separate plenums. Since the inlets and the plenums of the showerhead 500 are disjoint, the two separate process gases do not mix in the showerhead 500. While not shown, the design of the showerhead 500 can be extended to include additional disjoint inlets and plenums to supply additional process gases separately into the showerhead 500.

Additional differences between the showerhead 200 and the showerhead 500 are shown and described below with reference to FIGS. 41-49. Except for these differences, the showerhead 500 is similar to the showerhead 200. Therefore, identical reference numerals from the showerhead 200 are used to identify elements and features of the showerhead 500 that are similar to the respective elements and features of the showerhead 200, and their description is not repeated for brevity.

FIG. 41 shows that the showerhead 500 has the gas inlet 208 (hereinafter the first gas inlet 208) and a second gas inlet 508. The first and second gas inlets 208, 508 are coaxial. The second gas inlet 508 surrounds the first gas inlet 208 and is not in fluid communication with the first gas inlet 208. In addition to the plenum 224 (hereinafter the first plenum 224), the showerhead 500 further comprises a second plenum 502 arranged above the base portion 202 in the bottom center region 534 of the cylindrical base 207 of the backplate 204. The second plenum 502 abuts the top surface 205 of the base portion 202 and the bottom surface 211 of the cylindrical base 207 of the backplate 204. The second plenum 502 extends radially across the bottom center region 534 of the cylindrical base 207 as shown and described in detail with reference to FIGS. 43A-49.

Briefly, the second plenum 502 is located directly above the first plenum 224 and is not in fluid communication with the first plenum 224. Instead, as shown and described with reference to FIGS. 43A-49, top ends of the pillars 220 in the first plenum 224 abut the bottom of the second plenum 502. The top ends of the pillars 220 include through holes (shown in subsequent figures) that extend from the bottom of the second plenum 502, through the pillars 220, and through the bottom surface 213 of the base portion 202. Accordingly, the through holes in the pillars 220 are in fluid communication with the second plenum 502 but are not in fluid communication with the first plenum 224. In addition, as shown and described with reference to FIGS. 43A-49, the second plenum 502 comprises pillars similar to the pillars 220 in the first plenum 224 to increase the solidity and hence the heat conduction through the second plenum 502 as described below in further detail.

A first gas supplied by the gas delivery system 130 shown in FIG. 1B flows through the first gas inlet 208. Specifically, the first gas flows through an annular volume between an outer wall of the second gas inlet 508 and an inner wall of the first gas inlet 208. A second gas supplied by the gas delivery system 130 shown in FIG. 1B flows through the second gas inlet 508. As shown and described in further detail with reference to FIGS. 43A-49, the first and second gases flow through bores extending from the first and second gas inlets 208, 508 into the first and second plenums 224, 502, respectively.

FIG. 42 is identical to FIG. 3 except that in addition to showing all elements shown in FIG. 3, FIG. 42 shows the additional second gas inlet 508 described above.

FIG. 43A shows cross-sectional view of the showerhead 500 taken along lines A-A shown in FIG. 42. FIG. 43A is identical to FIG. 7A except for the following additions. Hereinafter, the bore 250 is called the first bore 250. A second bore 504 extends from the second gas inlet 508 vertically downwards towards the base portion 202. The second bore 504 extends through the stem portion 206 into the conical portion 209 of the backplate 204 along a vertical axis of the showerhead 500. The vertical axis of the showerhead 500 is similar to that of the showerhead 200 and is therefore not redefined for brevity. The second bore 504 extends through the center of the stem portion 206 and through the center of the backplate 204. The second bore 504 extends towards the bottom surface 211 of the cylindrical base 207 of the backplate 204. A distal end 505 of the bore 504 is connected to the second plenum 502 at the center of the second plenum 502. The second plenum 502 is shown and described below in further detail with reference to FIGS. 43B, 43C, 46, and 47.

FIG. 43B shows a side view of the bottom center region 534 of the cylindrical base 207 of the backplate 204 showing the second plenum 502 in further detail. The bottom center region 534 of the cylindrical base 207 lies between the upper region 506 of the cylindrical base 207 and the bottom surface 211 of the cylindrical base 207. That is, the bottom center region 534 of the cylindrical base 207 lies between the upper region 506 of the cylindrical base 207 and the top surface 205 of the base portion 202. The bottom center region 534 is concentric with the cylindrical base 207. The bottom center region 534 has a smaller diameter than the cylindrical base 207. The bottom center region 534 has a smaller diameter than the ID of the rim 203 of the base portion 202. The bottom center region 534 lies directly above the first plenum 224 in the base portion 202. The bottom center region 534 lies between distal ends of the bores 254 that connect to the first plenum 224 in the base portion 202 at 252-1 and 252-2.

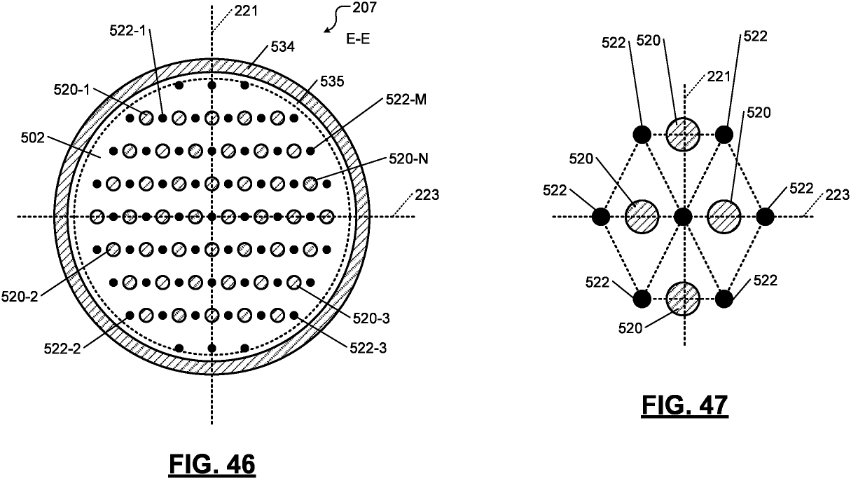

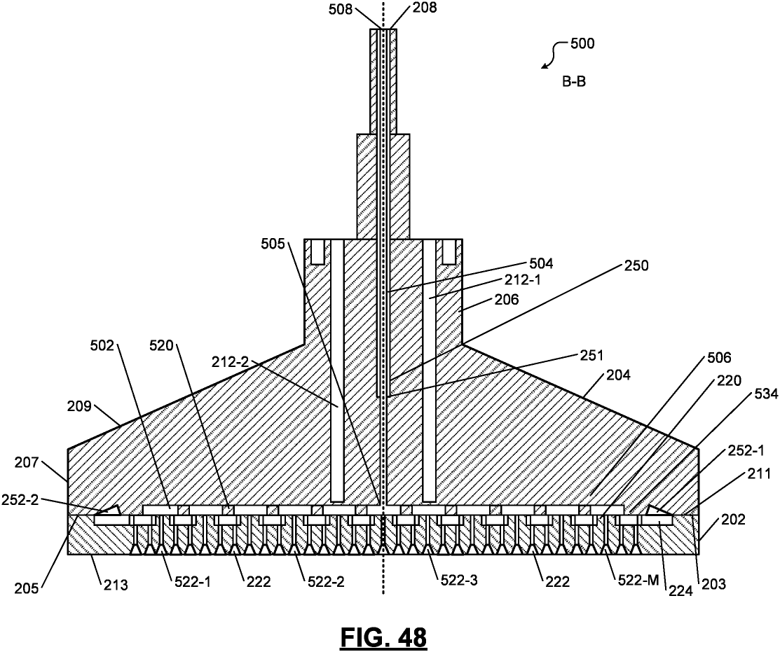

The second plenum 502 is formed in the bottom center region 534 by removing (by machining) material from the bottom center region 534 to form a recess 535 in the bottom center region 534. The recess 535 is cylindrical. The recess 535 has a smaller diameter than the bottom center region 534. The recess 535 and has a depth h1. A metal plate 550 having a slightly smaller diameter and less height than the bottom center region 534 is machined to form pillars 520, 520-2, 520-3, ..., and 520-N (collectively the pillars 520), where N is a positive integer. The pillars 520 extend vertically upwards into the recess 535 from the metal plate 550 parallel to the vertical axis of the showerhead 500. A combined height h2 of the metal plate 550 and the pillars 520 is equal to the depth h1 of the recess 535. Accordingly, when the metal plate 550 is inserted into the recess 535, the pillars 520 contact the upper edge of the recess 535 (i.e., the pillars 520 contact the bottom center region 534). The pillars 520 are distributed from the center of the bottom center region 534 towards an OD of the recess 535 in the bottom center region 534. The pillars 520 are interstitial but otherwise structurally and functionally similar to the pillars 220 in the first plenum 224 as described above with reference to the first showerhead 200 and as explained in further detail with reference to FIGS. 46 and 47.

The metal plate 550 is inserted into the recess 535 and is sealingly attached to the bottom center region 534 such that the bottom of the metal plate 550 is level (flush) with the bottom surface 211 of the cylindrical base 207. The second plenum 502 is defined by the bottom center region 534, the metal plate 550, the recess 535, and the pillars 520. The metal plate 550 separates and seals the second plenum 502 from the first plenum 224. When the metal plate 550 is sealingly attached to the bottom center region 534, the metal plate 550 prevents process gases from the two plenums from mixing with each other. Thus, the bottom center region 534 and the metal plate 550 define the second plenum 502.

The second plenum 502 extends radially across the bottom center region 534 of the cylindrical base 207. The second plenum 502 lies in a plane perpendicular to the vertical axis of the showerhead 500. The pillars 520 increase the solidity and hence the heat conduction through the second plenum 502 in the same manner as the pillars 220. That is, all of the characteristics (e.g., design features and constraints) of the pillars 220 described above with reference to the showerhead 200 apply equally to the pillars 520 and are therefore not repeated for brevity.

The second plenum 502 lies directly above the first plenum 224 in the base portion 202 along the vertical axis of the showerhead 500. Accordingly, when the base portion 202 with the first plenum 224 is attached to the backplate 204 with the intervening metal plate 550 between the first and second plenums 224, 502, the pillars 220 in the first plenum 224 abut the bottom of the second plenum 502. The pillars 220 in the first plenum 224 are interstitial to the pillars 520 in the second plenum 502 in the backplate 204.

FIG. 43C shows another way to define the second plenum 502. Instead of machining the metal plate 550 to form the pillars 520, the bottom center region 534 of the cylindrical base 207 can be machine to form the pillars 520 in the recess 535. The pillars 520 extend from the upper region 506 of the cylindrical base 207 through the recess 535. The pillars 520 extend towards the bottom surface 211 of the cylindrical base 207 parallel to the vertical axis of the showerhead 500. The height of the pillars 520 is equal to the depth h1 of the recess 535. The pillars 520 formed on the bottom center region 534 are otherwise identical to the pillars 520 formed on the metal plate 550 (shown in FIG. 43B). A metal plate 553 without the pillars 520 is sealingly attached to the bottom center region 534 in the same manner as the metal plate 550 is attached to the bottom center region 534 as described above to define the second plenum 502. The pillars 520 contact the metal plate 553. The base portion 202 with the first plenum 224 is attached to the backplate 204 with the metal plate 553 interposed between the first and second plenums 224, 502. The second plenum 502 is defined by the bottom center region 534, the metal plate 553, the recess 535, and the pillars 520.

The pillars 520 formed in the bottom center region 534 of the cylindrical base 207 increase the solidity and hence the heat conduction through the second plenum 502 in the same manner as the pillars 220. That is, all of the characteristics (e.g., design features and constraints) of the pillars 220 described above with reference to the showerhead 200 apply equally to the pillars 520 and are therefore not repeated for brevity.

FIG. 43D shows an alternate way to form both the first and second plenums 224, 502. For example, the recess 535 can be machined in bottom center region 534 of the cylindrical base 207. A recess 536 can be machined in the base portion 202 by removing material from the top surface 205 of the base portion 202. The recess 536 is also cylindrical and concentric with the base portion 202. A diameter of the recess 536 is equal to the ID of the rim 203 of the base portion 202. The diameter of the recess 536 is greater than the diameter of the recess 535. The recess 536 has a depth h3. The recess 536 extends radially in the base portion 202 up to 252-1, 252-2 to where the bores 254 connect to the base portion 202. Accordingly, when the base portion 202 is attached to the cylindrical base 207, the bores 254 are in fluid communication with the recess 536.

A metal plate 551 having a slightly smaller diameter than the bottom center region 534 can be machined to form the pillars 520, 220 on top and bottom surfaces of the metal plate 551. The pillars 520 extend vertically upwards into the recess 535 from the metal plate 551 parallel to the vertical axis of the showerhead 500. When the metal plate 551 is attached to the bottom center region 534 of the cylindrical base 207, the pillars 520 contact the upper edge of the recess 535 (i.e., the pillars 520 contact the bottom center region 534). The pillars 220 extend vertically downwards into the recess 536 from the metal plate 551 parallel to the vertical axis of the showerhead 500. When the metal plate 551 is attached to the bottom center region 534 of the cylindrical base 207 and the base portion 202 is attached to the cylindrical base 207, the pillars 220 contact the lower edge of the recess 536 (i.e., the pillars 220 contact the base portion 202).

When the metal plate 551 is sealingly attached to the bottom center region 534 of the cylindrical base 207 as described above, the second plenum 502 is defined by the bottom center region 534, the top surface of the metal plate 551, the recess 535, and the pillars 520. Thereafter, when the base portion 202 is sealingly attached to the cylindrical base 207, the first plenum 224 is defined by the base portion 202, the bottom surface of the metal plate 551, the recess 536, and the pillars 220. When the metal plate 551 is sealingly attached to the bottom center region 534 of the cylindrical base 207, the bottom surface of the metal plate 551 is level (flush) with the bottom surface 211 of the cylindrical base 207. Accordingly, when the base portion 202 is sealingly attached to the cylindrical base 207, the pillars 220 extend below the bottom surface 211 of the cylindrical base 207 into the first plenum 224 and abut the bottom of the recess 536 in the base portion 202. Accordingly, the through holes 522 can be drilled from the bottom surface 213 of the base portion 202 through the pillars 520 into the second plenum 502.

The recess 535 has a depth h1 as described above. The recess 536 has a depth h3. A height h2 from the bottom surface of the metal plate 550 and to the top of the pillars 520 is equal to the depth h1 of the recess 535. A height h4 of the pillars 220 is equal to the depth h3 of the recess 536. The combined thickness of the metal plate 551 measured from the top of the pillars 520 to the bottom of the pillars 220 is h2+h3. The pillars 520 are distributed from the center of the bottom center region 534 towards an OD of the recess 535 in the bottom center region 534. The pillars 220 are distributed from the center of the base portion 202 towards an OD of the recess 536 in the base portion 202. The pillars 520 are interstitial with the pillars 220 in the first plenum 224 and align with through holes 522 (described below). The through holes 222 are drilled from the bottom surface 213 of the base portion 202 into the recess 536 (i.e., into the first plenum 224). The through holes 522 are drilled from the bottom surface 213 of the base portion 202, through the metal plate 551 (i.e., through the pillars 520) into the recess 535 (i.e., into the second plenum 502). Thus, the first and second plenums 224, 502 are disjoint (i.e., not in fluid communication with each other).

The pillars 520 and 230 formed on the metal plate 551 increase the solidity and hence the heat conduction through the first and second plenums 224, 502 in the same manner as the pillars 220. That is, all of the characteristics (e.g., design features and constraints) of the pillars 220 described above with reference to the showerhead 200 apply equally to the pillars 520 and 230 formed on the metal plate 551 and are therefore not repeated for brevity.

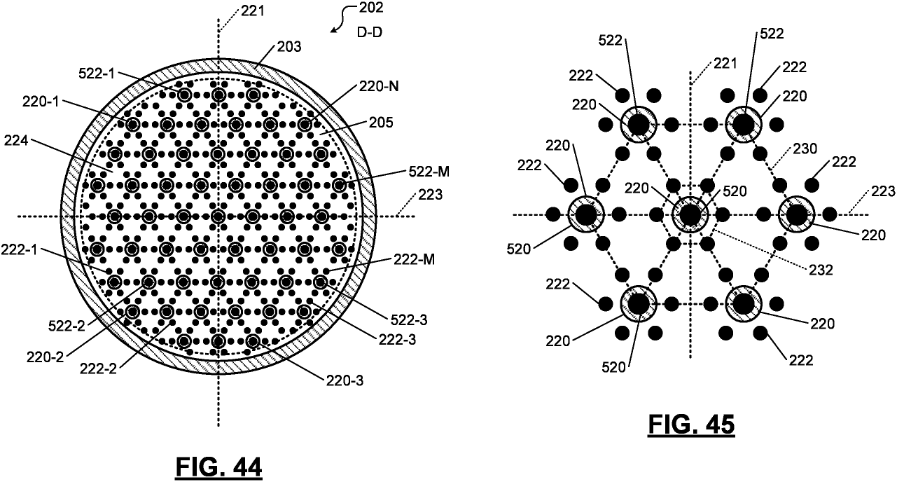

In FIG. 43A, a plurality of through holes 522-1, 522-2, 522-3, ..., and 522-M (collectively the through holes 522), where M is a positive integer, are drilled through the bottom surface 213 of the base portion 202. The through holes 522 are drilled through the center of the pillars 220 (one through hole 522 per pillar 220) and through the metal plate 550 shown in FIGS. 43B and 43C. The through holes 522 are in fluid communication with the second plenum 502 but are not in fluid communication with the first plenum 224. As shown and described in further detail with reference to FIGS. 44-47, the pillars 520 of the second plenum 502 are arranged interstitially with the pillars 220. The through holes 522 of the second plenum 502 are arranged interstitially with the through holes 222.

The first gas flows through the first gas inlet 208, through the bores 250 and 254, the first plenum 224, and the through holes 222 into the processing chamber 102 shown in FIG. 1B. The second gas flows through the second gas inlet 508, through the bore 504, the second plenum 502, and the through holes 522 in the pillars 220 into the processing chamber 102 shown in FIG. 1B. The remaining features shown in FIG. 43A are shown and described with reference to FIG. 7A and their description is therefore omitted for brevity.

FIGS. 44 and 45 show a top view of a cross-section of the base portion 202 taken along lines D-D shown in FIG. 41 showing the first plenum 224 in detail. FIG. 45 shows the pattern of elements 220, 222, 520, and 522 in greater detail than in FIG. 44. The top view of the cross-section of the base portion 202 is described with reference to both FIGS. 44 and 45. FIGS. 44 and 45 are identical to FIGS. 4 and 5 except that unlike in FIGS. 4 and 5, in FIGS. 44 and 45, the pillars 220 of the first plenum 224 additionally include the through holes 522 (one through hole 522 per pillar 220). The through holes 522 are drilled through the bottom surface 213 of the base portion 202, the pillars 220 of the first plenum 224, the top surface 205 of the base portion 202, and the metal plate 550. Thus, the through holes 522 are in fluid communication with the second plenum 502 but are not in fluid communication with the first plenum 224. The through holes 522 are distributed from the center of the bottom center region 534 towards the OD of the bottom center region 534. The through holes 522 follow the geometrical arrangement of the pillars 220, which is described with reference to FIGS. 4 and 5 and is therefore not repeated for brevity.

FIGS. 46 and 47 show a top view of a cross-section of the bottom center region 534 of the cylindrical base 207 of the backplate 204 taken along lines E-E shown in FIG. 41 showing the second plenum 502 in detail. FIG. 46 shows the arrangement of the pillars 520 and the through holes 522 of the second plenum 502. FIG. 47 shows the pattern of the pillars 520 and the through holes 522 in detail.

In FIG. 46, the pillars 520 and the through holes 522 are arranged in the second plenum 502 along the first and second axes 221, 223. The pillars 520 and the through holes 522 are arranged such that one through hole 522 lies between two pillars 520 along the first and second axes 221, 223.

In FIG. 47, the through holes 522 are arranged on the vertices of the hexagon 230. One through hole 522 lies at the center of the hexagon 230. Consequently, since the pillars 220 of the first plenum 224, which lies directly below the second plenum 502, are also arranged on the vertices and at the center of the hexagon 230, each through hole 522 of the second plenum 502 aligns with a pillar 220 of the first plenum 224 along the vertical axis of the showerhead 500.

Additionally, in each hexagon 230, one pillar 520 lies between two through holes 522 along the first and second axes 221, 223. Accordingly, each pillar 520 of the second plenum 502 lies above two through holes 222 of the first plenum 224 that lie between two pillars 220 arranged in the hexagon 230 in the first plenum 224 as shown in FIG. 45. Thus, the pillars 520 in the second plenum 502 are interstitial to the pillars 220 in the first plenum 224. The through holes 522 in the second plenum 502 not only align with the pillars 220 in the first plenum 224 but are also interstitial to the through holes 222 in the first plenum 224.

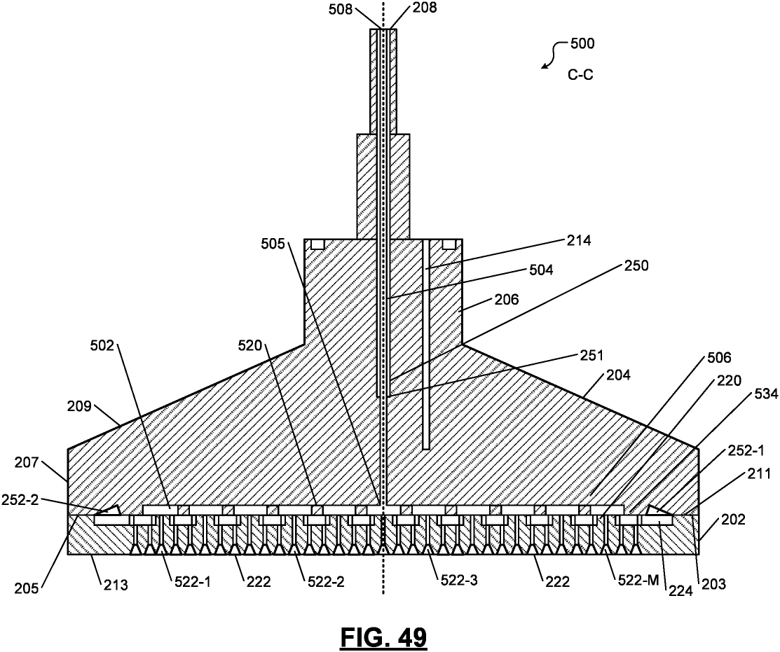

FIG. 48 shows a cross-section of the showerhead 500 taken along lines B-B shown in FIG. 42. FIG. 48 is identical to FIG. 6 except that in addition to showing all of the elements shown in FIG. 6, FIG. 48 shows the additional second gas inlet 508, the bore 504, and the second plenum 502 with the pillars 520 and the through holes 522 described above.

FIG. 49 shows a cross-section of the showerhead 200 taken along lines C-C shown in FIG. 42. FIG. 48 is identical to FIG. 6 except that in addition to showing all of the elements shown in FIG. 6, FIG. 48 shows the additional second gas inlet 508, the bore 504, and the second plenum 502 with the pillars 520 and the through holes 522 described above.

Throughout the present disclosure, references are made to hexagons and hexagonal patterns of the pillars and through holes. As used herein, a hexagon comprises a regular-hexagon. Alternatively, a hexagonal pattern can also be viewed as including patterns arranged in equilateral triangles. Accordingly, in the hexagonal patterns of the pillars and through holes described above, a hexagonal unit cell of the pillars and through holes can include a regular-hexagon-shaped unit cell or an equilateral-triangular-shaped unit cell.

Further, throughout present disclosure, the gas inlets of the dual plenum showerheads are shown and described as being coaxial. Instead, the gas inlets and corresponding bores can be arranged side-by-side (i.e., adjacent to each other). Alternatively, the inlets and the respective bores can be arranged in other ways.

The foregoing description is merely illustrative in nature and is not intended to limit the disclosure, its application, or uses. The broad teachings of the disclosure can be implemented in a variety of forms. Therefore, while this disclosure comprises particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead comprising:
a base portion;
a backplate of a different shape than the base portion extending from the base portion; and
a plurality of pillars arranged in a plenum defined between a first region of the base portion and a second region of the backplate within sidewalls of the base portion and the second region of the backplate, the pillars extending vertically between the base portion and the second region of the backplate.

2. The showerhead of claim 1 wherein:
the base portion is cylindrical; and
the backplate comprises a cylindrical base and a conical portion, the cylindrical base is attached to the base portion, and the conical portion extends from the cylindrical base.

3. The showerhead of claim 2 wherein the backplate comprises a recess in a bottom region abutting the base portion and wherein the base portion comprises the pillars that extend through the recess and contact the cylindrical base.

4. The showerhead of claim 2 wherein the base portion comprises a recess in the first region abutting the cylindrical base and wherein the cylindrical base comprises the pillars that extend through the recess and contact the base portion.

5. The showerhead of claim 3 further comprising a stem portion attached to the conical portion of the backplate wherein:
the stem portion comprises a gas inlet; and
the conical portion comprises a plurality of bores in fluid communication with the gas inlet, the bores extending towards the base portion and connecting to the plenum.

6. The showerhead of claim 2 further comprising a stem portion attached to the conical portion of the backplate wherein the backplate comprises a plurality of bores extending from the stem portion towards the base portion for receiving a plurality of heaters, respectively.

7. The showerhead of claim 2 further comprising a stem portion attached to the conical portion of the backplate wherein the backplate comprises one or more bores extending from the stem portion towards the base portion for receiving one or more temperature sensors, respectively.

8. The showerhead of claim 2 further comprising a stem portion attached to the conical portion of the backplate wherein:
the stem portion comprises a gas inlet; and
the backplate comprises:
a first plurality of bores in fluid communication with the gas inlet, the first plurality of bores extending towards the base portion and connecting to the plenum;
a second plurality of bores extending from the stem portion towards the base portion for receiving a plurality of heaters, respectively; and
one or more bores extending from the stem portion towards the base portion for receiving one or more temperature sensors, respectively;
wherein the first and second plurality of bores and the one or more bores are interstitial to each other.

9. The showerhead of claim 2 wherein the base portion comprises a plurality of through holes extending vertically from a bottom surface of the base portion to the plenum and wherein the through holes are arranged interstitially with the pillars.

10. The showerhead of claim 9 wherein the pillars are arranged in a first pattern and wherein each of the pillars is surrounded by a set of the through holes arranged in a second pattern.

11. The showerhead of claim 10 wherein the first and second patterns are traingular.

12. The showerhead of claim 8 wherein the base portion comprises a plurality of through holes extending vertically from a bottom surface of the base portion to the plenum and wherein the through holes are arranged interstitially with the pillars.

13. The showerhead of claim 2 wherein diameters of the base portion and the cylindrical base are equal.

14. A showerhead comprising:
a base portion;
a backplate of a different shape than the base portion extending from the base portion, the backplate and the base portion being monolithic; and
a plurality of pillars arranged in a plenum defined within sidewalls of the base portion, the pillars extending vertically towards the backplate.

15. The showerhead of claim 14 wherein:
the base portion is cylindrical; and
the backplate comprises a conical portion extending from the base portion, the conical portion and the base portion being monolithic.

16. The showerhead of claim 15 wherein:
the base portion comprises a plurality of sets of bores extending across the base portion;
the sets of bores intersect each other; and
intersections of the sets of bores define the pillars.

17. The showerhead of claim 16 wherein the sets of bores have first openings on the sidewalls of the base portion, the showerhead further comprising a stem portion extending from the conical portion wherein:
the stem portion comprises a gas inlet; and
the conical portion comprises a plurality of bores in fluid communication with the gas inlet, the plurality of bores extending towards the base portion and comprising second openings on the sidewalls of the base portion above the first openings; and
the showerhead further comprises an annular sealing member attached to the base portion below the first openings and to the conical portion above the second openings defining an annular volume in fluid communication with the plenum.

18. The showerhead of claim 15 further comprising a stem portion extending from the conical portion wherein the conical portion comprises a plurality bores extending from the stem portion towards the base portion for receiving a plurality of heaters, respectively.

19. The showerhead of claim 15 further comprising a stem portion extending from the conical portion wherein the conical portion comprises one or more bores extending from the stem portion towards the base portion for receiving one or more temperature sensors, respectively.

20. The showerhead of claim 16 further comprising a stem portion extending from the conical portion wherein:
the stem portion comprises a gas inlet; and
the conical portion comprises:
a first plurality of bores in fluid communication with the gas inlet, the first plurality of bores extending towards the base portion and connecting to the plenum;
a second plurality of bores extending from the stem portion towards the base portion for receiving a plurality of heaters, respectively; and
one or more bores extending from the stem portion towards the base portion for receiving one or more temperature sensors, respectively;
wherein the first and second plurality of bores and the one or more bores are interstitial to each other.

21. The showerhead of claim 20 wherein the sets of bores have first openings on the sidewalls of the base portion and the plurality of bores have second openings on the sidewalls of the base portion above the first openings, the showerhead further comprising:
an annular sealing member attached to the base portion below the first openings and to the conical portion above the second openings defining an annular volume in fluid communication with the plenum.

22. The showerhead of claim 17 wherein the conical portion comprises:
a second plurality of bores extending from the stem portion towards the base portion for receiving a plurality of heaters, respectively; and
one or more bores extending from the stem portion towards the base portion for receiving one or more temperature sensors, respectively;
wherein the plurality of bores, the second plurality of bores, and the one or more bores are interstitial to each other.

23. The showerhead of claim 15 wherein the base portion comprises a plurality of through holes extending vertically from a bottom surface of the base portion to the plenum and wherein the through holes are arranged interstitially with the pillars.

24. The showerhead of claim 23 wherein the pillars are arranged in a first pattern and wherein each of the pillars is surrounded by a set of the through holes arranged in a second pattern.

25. The showerhead of claim 24 wherein the first and second patterns are square patterns.

26. The showerhead of claim 23 wherein a first set of the through holes is arranged in a first pattern in a first region of the base portion and wherein a second set of the through holes is arranged in a second pattern in a second region of the base portion.

27. The showerhead of claim 26 wherein the first and second regions are concentric.

28. The showerhead of claim 17 wherein the base portion comprises a plurality of through holes extending vertically from a bottom surface of the base portion to the plenum and wherein the through holes are arranged interstitially with the pillars.

29. The showerhead of claim 20 wherein the base portion comprises a plurality of through holes extending vertically from a bottom surface of the base portion to the plenum and wherein the through holes are arranged interstitially with the pillars.

30. The showerhead of claim 21 wherein the base portion comprises a plurality of through holes extending vertically from a bottom surface of the base portion to the plenum and wherein the through holes are arranged interstitially with the pillars.

31. The showerhead of claim 22 wherein the base portion comprises a plurality of through holes extending vertically from a bottom surface of the base portion to the plenum and wherein the through holes are arranged interstitially with the pillars.
